(19) United States
(12) Patent Application Publication
(10) Pub. No.: US 2026/0075856 A1
(43) Pub. Date: Mar. 12, 2026

(54) SEMICONDUCTOR DEVICE AND METHOD

(71) Applicant: Taiwan Semiconductor Manufacturing Co., Ltd., Hsinchu (TW)

(72) Inventors: Wan-Yi Kao, Baoshan Township (TW); Chunyao Wang, Zhubei (TW); Tai-Chun Huang, Hsinchu (TW); Tze-Liang Lee, Hsinchu (TW)

(21) Appl. No.: 18/826,620

(22) Filed: Sep. 6, 2024

(51) Int. Cl. H01L 29/66; H01L 29/06; H01L 29/423; H01L 29/775; H01L 29/786

(52) U.S. Cl. CPC H10D 30/014; H10D 30/43; H10D 30/6735; H10D 30/6757; H10D 62/121; H10D 64/017

(57) ABSTRACT

A method includes forming a first fin structure and a second fin structure that protrude above a substrate, forming shallow trench isolation (STI) regions on opposing sides of each the first fin structure and the second fin structure, depositing a hard mask layer over the STI regions and top surfaces of the first fin structure and the second fin structure, and on sidewalls of the first fin structure and the second fin structure, depositing a capping layer over the hard mask layer, performing a first etching process to remove first portions of the capping layer and expose first portions of the hard mask layer, performing a second etching process to remove the exposed first portions of the hard mask layer, and forming a dummy gate structure over the first fin structure, the second fin structure, and remaining portions of the hard mask layer.

### BACKGROUND

Semiconductor devices are used in a variety of electronic applications, such as, for example, personal computers, cell phones, digital cameras, and other electronic equipment. Semiconductor devices are typically fabricated by depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a nanostructure field-effect transistor (NSFET) device in a three-dimensional view, in accordance with some embodiments.

FIGS. 2, 3A, 3B, 4A, 4B, 5A, 5B, 6A, 6B, 7A, 7B, 8A, 8B, 9A, 9B, 10A, 10B, 11A, 11B, 11C 12A, 12B, 12C, 13A, 13B, 13C, 14A, 14B, 14C, 15A, 15B, 15C, 16A, 16B, 16C, 17A, 17B, 17C, 18A, 18B, 18C, 19A, 19B, 20A, 20B, 21A, 21B, 22A, 22B, 23A, and 23B are cross-sectional views of a portion of a nanostructure field-effect transistor (NSFET) device at various stages of manufacturing, in accordance with an embodiment.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Various embodiments provide semiconductor devices having improved performance and methods of forming the same. The semiconductor devices may be nanostructure field-effect transistors (nano-FETs, also referred to as nanosheet field-effect transistors (NSFETs), nanowire field-effect transistors (NWFETs), or gate-all-around field-effect transistors (GAAFETs)). These embodiments include methods applied to forming a semiconductor device that include forming a first fin structure and a second fin structure adjacent to the first fin structure, wherein the first fin structure and the second fin structure protrude above a substrate. A shallow trench isolation (STI) region is disposed between the first fin structure and the second fin structure, the first fin structure and the second fin structure protruding above a top surface of the STI region. Each of the first fin structure and the second fin structure includes a fin and a layer stack over the fin, where the layer stack comprises alternating layers of a first semiconductor material and a second semiconductor material. A dielectric liner and a hard mask layer are sequentially formed over the STI region, and on top surfaces and sidewalls of portions of the first fin structure and the second fin structure that protrude above the STI region. An oxide capping layer may then be formed over the hard mask layer. A Bottom Anti-Reflective Coating (BARC) layer may be formed over the oxide capping layer in order to fill in a trench between the first fin structure and the second fin structure. A first etching process may be performed to etch-back the BARC layer, and a second etching process may be performed subsequently to remove portions of the oxide capping layer (e.g., on sidewalls and over top surfaces of the first fin structure and the second fin structure) that are above a top surface of the etched-back BARC layer. The etched-back BARC layer is then removed, and a third etching process is performed to remove exposed portions (e.g., portions not protected by and not underlying the oxide capping layer) of the hard mask layer that are over the top surfaces of the first fin structure and the second fin structure, as well as that are on sidewalls of upper portions of the first fin structure and the second fin structure. After the third etching process, remaining portions of the hard mask layer are disposed over the STI region and on sidewalls of lower portions of the first fin structure and the second fin structure. In addition, after the third etching process is performed, portions of the dielectric liner on the top surfaces of the first fin structure and the second fin structure, as well as on the sidewalls of the upper portions of the first fin structure and the second fin structure are exposed. A fourth etching process is performed subsequently to remove the remaining portions of the oxide capping layer, portions of the hard mask layer on sidewalls of the first fin structure and the second fin structure, and portions of the dielectric liner that are disposed on sidewalls and top surfaces of the first fin structure and the second fin structure. Advantageous features of one or more embodiments disclosed herein may include the oxide capping layer reducing a risk of unwanted etching of the underlying hard mask layer during the first etching process, the third etching process, and the fourth etching process. As a result, unwanted etching of the hard mask layer and resulting thickness non-uniformities of the hard mask layer can be reduced. In addition, a larger and uniform thickness of the hard mask layer can be maintained over the top surfaces of the first fin structure and the second fin structure, as well as over the STI region. For example, horizontal portions of the hard mask layer that are disposed over the top surfaces of the first fin structure and the second fin structure that have a reduced thickness and have thickness non-uniformities would increase a risk of etching damage and rounding of top corners of the layer stack (e.g., that include subsequently formed channel layers) during subsequent etching processes that may be performed to remove these horizontal portions of the hard mask layer. By reducing these thickness non-uniformities of the hard mask layer, device characteristics and performance can be preserved, and device reliability is increased. In addition, during a subsequent selective etching process that is used to release the second semiconductor material of the layer stack to form nanostructures of the semiconductor device, the larger thickness of the hard mask layer over the STI region is able to provide increased protection to portions of the STI region from the selective etching process, and therefore, prevent or reduce loss of the STI region due to the selective etching process. As a result, device reliability can be improved.

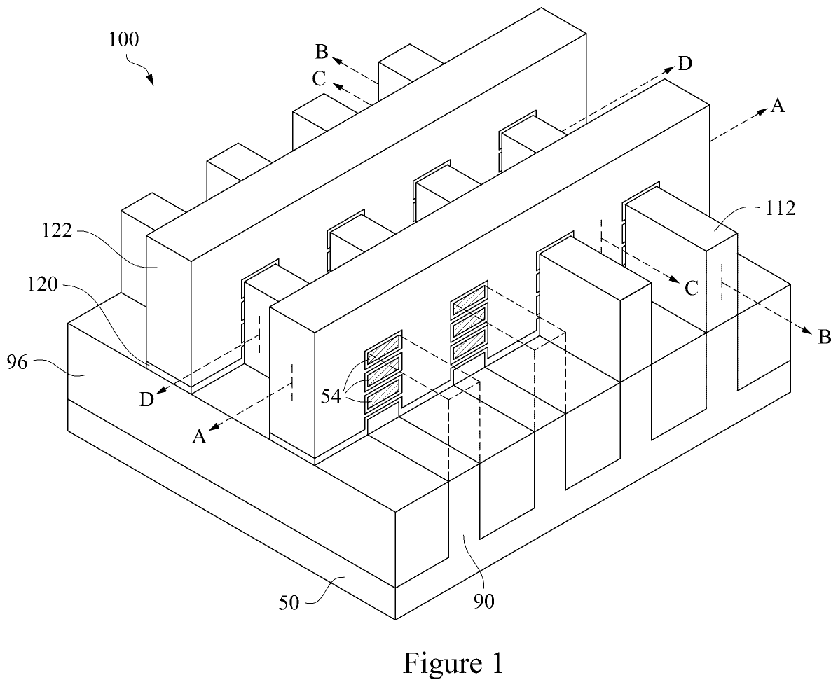

FIG. 1 illustrates an example of a nanostructure field-effect transistor (NSFET) device 100 in a three-dimensional view, in accordance with some embodiments. The NSFET device 100 comprises semiconductor fins 90 (also referred to as fins) protruding above a substrate 50. Gate electrodes 122 (e.g., metal gates) are disposed over the fins, and source/drain regions 112 are formed on opposing sides of the gate electrodes 122. A plurality of nanostructures 54 (e.g., nanowires, or nanosheets) are formed over the fins 90 and between source/drain regions 112. Shallow trench isolation (STI) regions 96 are formed on opposing sides of the fins 90. A gate dielectric layer 120 is formed around the nanostructures 54. Gate electrodes 122 are formed over and around the gate dielectric layer 120.

FIG. 1 further illustrates reference cross-sections that are used in later figures. Cross-section A-A is along a longitudinal axis of the gate electrode 122 and in a direction, for example, perpendicular to the direction of current flow between the source/drain regions 112 of the NSFET device 100. Cross-section B-B is perpendicular to cross-section A-A and is along a longitudinal axis of the fin 90 and in a direction of, for example, a current flow between the source/drain regions 112 of the NSFET device 100. Cross-section C-C is parallel to cross-section B-B and between two neighboring fins 90. Cross-section D-D is parallel to cross-section A-A and extends through source/drain regions 112 of the NSFET device 100. Subsequent figures may refer to these reference cross-sections for clarity.

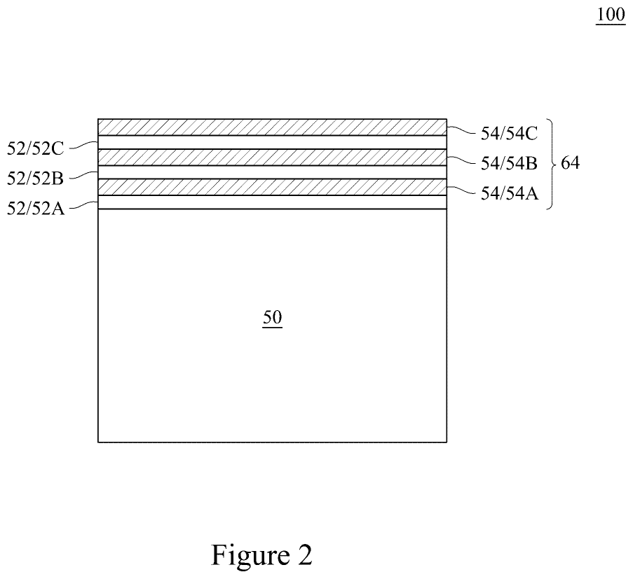

FIGS. 2, 3A, 3B, 4A, 4B, 5A, 5B, 6A, 6B, 7A, 7B, 8A, 8B, 9A, 9B, 10A, 10B, 11A, 11B, 11C, 12A, 12B, 12C, 13A, 13B, 13C, 14A, 14B, 14C, 15A, 15B, 15C, 16A, 16B, 16C, 17A, 17B, 17C, 18A, 18B, 18C, 19A, 19B, 20A, 20B, 21A, 21B, 22A, 22B, 23A and 23B are cross-sectional views of a portion of the nanostructure field-effect transistor (NSFET) device 100 at various stages of manufacturing, in accordance with an embodiment.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon substrate or a glass substrate. Other substrates, such as a multi-layered or gradient substrate may also be used. In some embodiments, the semiconductor material of the substrate 50 includes silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof.

A multi-layer stack 64 is formed on the substrate 50. The multi-layer stack 64 includes alternating layers of a first semiconductor material 52 and a second semiconductor material 54. In FIG. 2, layers formed by the first semiconductor material 52 are labeled as 52A, 52B, and 52C, and layers formed by the second semiconductor material 54 are labeled as 54A, 54B, and 54C. The number of layers formed by the first and the semiconductor materials illustrated in FIG. 2 are merely non-limiting examples. Other numbers of layers are also possible and are fully intended to be included within the scope of the present disclosure.

In some embodiments, the first semiconductor material 52 is a first type of epitaxial material, such as silicon germanium (SiₓGe₁₋ₓ, where x can be in the range of 0 to 1), and the second semiconductor material 54 is a second type of epitaxial material, such as silicon. The multi-layer stack 64 (which may also be referred to as an epitaxial material stack) will be patterned to form channel regions of an NSFET in subsequent processing. In particular, the multi-layer stack 64 will be patterned and etched to form nanostructures (e.g., nanosheets or nanowires), with the channel regions of the resulting NSFET including multiple horizontally extending nanostructures.

The multi-layer stack 64 may be formed by an epitaxial growth process, which may be performed in a growth chamber. During the epitaxial growth process, the growth chamber is cyclically exposed to a first set of precursors for selectively growing the first semiconductor material 52, and then exposed to a second set of precursors for selectively growing the second semiconductor material 54, in some embodiments. The first set of precursors includes precursors for the first semiconductor material 52 (e.g., silicon germanium), and the second set of precursors includes precursors for the second semiconductor material 54 (e.g., silicon). In some embodiments, the first set of precursors includes a silicon precursor (e.g., silane) and a germanium precursor (e.g., a germane), and the second set of precursors includes the silicon precursor but omits the germanium precursor. The epitaxial growth process may thus include continuously enabling a flow of the silicon precursor to the growth chamber, and then cyclically: (1) enabling a flow of the germanium precursor to the growth chamber when growing the first semiconductor material 52; and (2) disabling the flow of the germanium precursor to the growth chamber when growing the second semiconductor material 54. The cyclical exposure may be repeated until a target number of layers is formed.

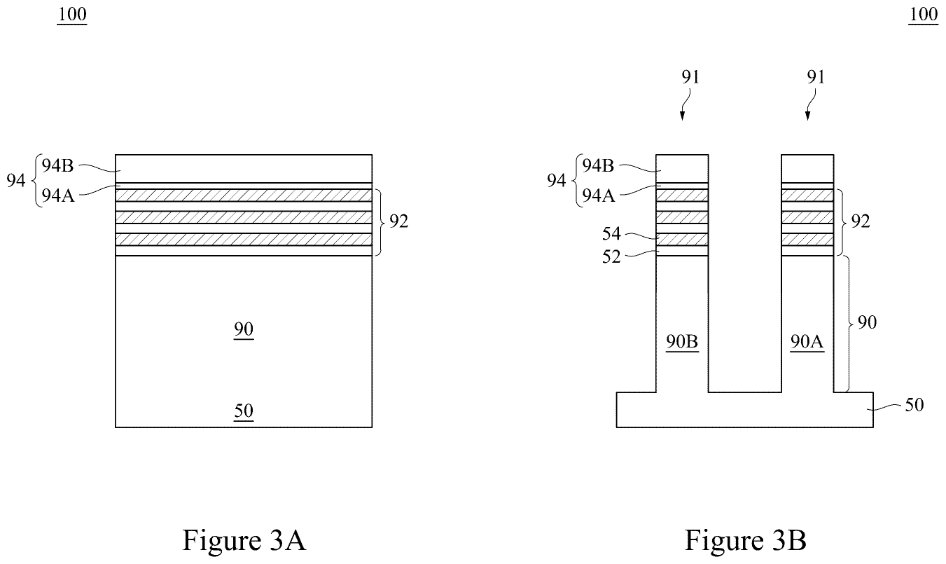

FIGS. 3A, 3B, 4A, 4B, 5A, 5B, 6A, 6B, 7A, 7B, 8A, 8B, 9A, 9B, 10A, 10B, 11A, 11B, 11C, 12A, 12B, 12C, 13A, 13B, 13C, 14A, 14B, 14C, 15A, 15B, 15C, 16A, 16B, 16C, 17A, 17B, 17C, 18A, 18B, 18C, 19A, 19B, 20A, 20B, 21A, 21B, 22A, 22B, 23A, and 23B are cross-sectional views of the NSFET device 100 at subsequent stages of manufacturing, in accordance with an embodiment. FIGS. 3A, 4A, 5A, 6A, 7A, 8A, 9A, 10A, 11A, 12A, 13A, 14A, 15A, 16A, 17A, 18A, 19A, 20A, 21A, 22A, and 23A are cross-sectional views along cross-section B-B in FIG. 1. FIGS. 3B, 4B, 5B, 6B, 7B, 8B, 9B, 10B, 11B, 11C, 12C, 13C, 14C, 15C, 16C, 17C, 18C, 19B, 20B, 21B, 22B, and 23B are cross-sectional views along cross-section A-A in FIG. 1. FIGS. 12B, 13B, 14B, 15B, 16B, 17B, and 18B are cross-sectional views along cross-section D-D in FIG. 1. The number of fins and the number of gate structures illustrated in the figures are merely non-limiting examples, it should be appreciated that other numbers of fins and other numbers of gate structures may also be formed.

In FIGS. 3A and 3B, fin structures 91 are formed protruding above the substrate 50. Each of the fin structures 91 includes a semiconductor fin 90 (also referred to as a fin) and a layer stack 92 overlying the semiconductor fin 90. The layer stack 92 and the semiconductor fin 90 may be formed by etching trenches in the multi-layer stack 64 and the substrate 50, respectively. The layer stack 92 and the semiconductor fin 90 may be formed by a same etching process.

The fin structures 91 may be patterned by any suitable method. For example, the fin structures 91 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern, e.g., the fin structures 91.

In some embodiments, the remaining spacers are used to pattern a mask 94, which is then used to pattern the fin structures 91. The mask 94 may be a single layer mask, or may be a multilayer mask such as a multilayer mask that includes a first mask layer 94A and a second mask layer 94B. The first mask layer 94A and the second mask layer 94B may each be formed from a dielectric material such as silicon oxide, silicon nitride, a combination thereof, or the like, and may be deposited or thermally grown according to suitable techniques. The first mask layer 94A and the second mask layer 94B are different materials having a high etching selectivity. For example, the first mask layer 94A may be silicon oxide, and the second mask layer 94B may be silicon nitride. The mask 94 may be formed by patterning the first mask layer 94A and the second mask layer 94B using any acceptable etching process. The mask 94 may then be used as an etching mask to etch the substrate 50 and the multi-layer stack 64. The etching may be any acceptable etching process, such as a reactive ion etch (RIE), neutral beam etch (NBE), the like, or a combination thereof. The etching is an anisotropic etching process, in some embodiments. After the etching process, the patterned multi-layer stack 64 forms the layer stack 92, and the patterned portion of the substrate 50 forms the fin 90 (e.g., 90A or 90B), as illustrated in FIGS. 3A and 3B. The remaining (e.g., un-patterned) portion of the substrate 50 is referred to as the substrate 50 in FIGS. 3A and 3B and subsequent figures. Therefore, in the illustrated embodiment, the layer stack 92 also includes alternating layers of the first semiconductor material 52 and the second semiconductor material 54. The fin 90 is formed of a same material as the substrate 50. In the example of FIGS. 3A and 3B, fins 90A and 90B are formed to extend parallel to each other.

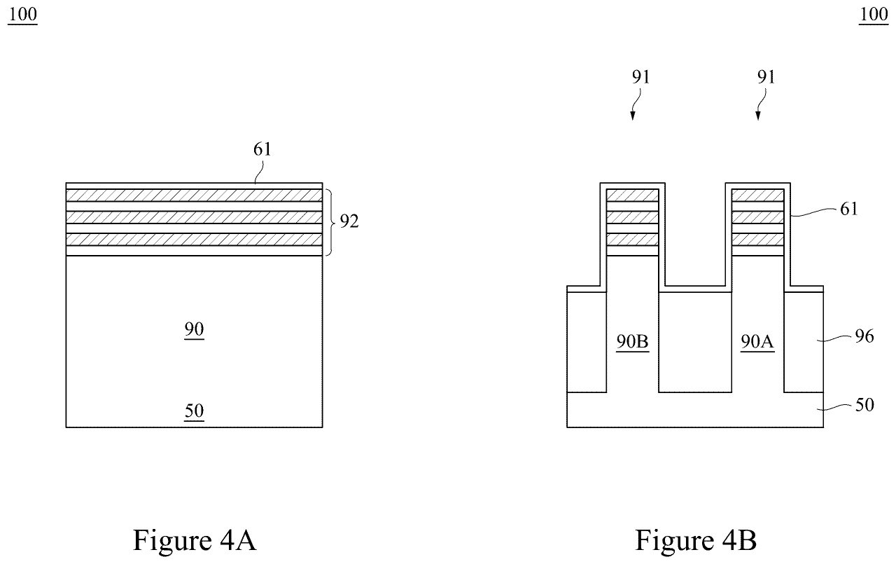

Next, in FIGS. 4A and 4B, shallow trench isolation (STI) regions 96 are formed over the substrate 50 and on opposing sides of the fin structures 91. As an example to form the STI regions 96, an insulation material may be formed over the substrate 50. The insulation material may be an oxide such as silicon oxide, a nitride, the like, or a combination thereof, and may be formed by a high-density plasma chemical vapor deposition (HDP-CVD), a flowable CVD (FCVD) (e.g., a CVD-based material deposition in a remote plasma system and post curing to make it convert to another material, such as an oxide), the like, or a combination thereof. Other insulation materials formed by any acceptable process may be used. In the illustrated embodiment, the insulation material is silicon oxide formed by an FCVD process. An anneal process may be performed after the insulation material is formed.

In some embodiments, the insulation material is formed such that excess insulation material covers the fin structures 91. In some embodiments, a liner is first formed along surfaces of the substrate 50 and fin structures 91, and a fill material, such as those discussed above is formed over the liner. In some embodiments, the liner is omitted.

Next, a removal process is applied to the insulation material to remove excess insulation material disposed over the fin structures 91. In some embodiments, a planarization process such as a chemical mechanical polish (CMP), an etch back process, combinations thereof, or the like, may be utilized. The planarization process exposes the layer stacks 92 such that top surfaces of the layer stacks 92 and the insulation material are level after the planarization process is complete. Next, the insulation material is recessed to form the STI regions 96. The insulation material is recessed such that the layer stacks 92 protrude from between neighboring STI regions 96. Top portions of the semiconductor fins 90 may also protrude from between neighboring STI regions 96. Further, the top surfaces of the STI regions 96 may have a flat surface as illustrated, a convex surface, a concave surface (such as dishing), or a combination thereof. The top surfaces of the STI regions 96 may be formed flat, convex, and/or concave by an appropriate etch. The STI regions 96 may be recessed using an acceptable etching process, such as one that is selective to the material of the insulation material (e.g., etches the material of the insulation material at a faster rate than the material of the fin 90 and the layer stack 92). For example, a chemical oxide removal with a suitable etchant such as dilute hydrofluoric (dHF) acid may be used.

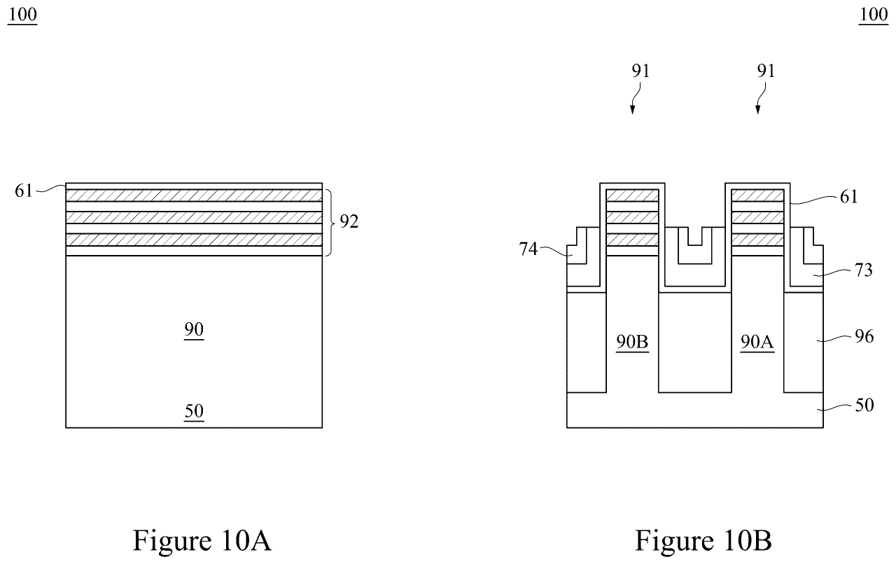

Still referring to FIGS. 4A and 4B, a dielectric liner 61 is formed over the layer stacks 92 and over the STI regions 96, such as over top surfaces of the fin structures 91 and the STI regions 96, as well as sidewalls of portions of the fin structures 91 that are above the STI regions 96. The dielectric liner 61 may be a suitable dielectric material such as silicon oxide, and may be formed using a suitable deposition method such as CVD, atomic layer deposition (ALD), or the like. The dielectric liner 61 protects the layer stacks 92 from damage by subsequent etching process(es) that are used to etch a hard mask layer 73 (shown subsequently in FIGS. 10A and 10B), in some embodiments. The dielectric liner 61 may also be referred to as an oxide liner layer. Besides silicon oxide, other suitable material, such as a dielectric material that provides high etching selectivity from the layer stack 92 and the subsequently formed hard mask layer 73 may also be used.

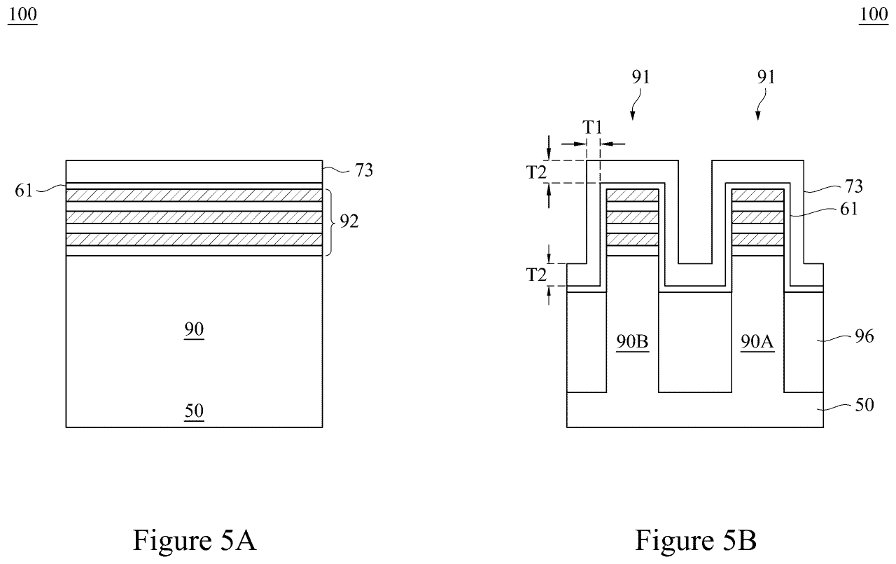

Next, in FIGS. 5A and 5B, a hard mask layer 73 is formed over the dielectric liner 61. The hard mask layer 73 is formed of a material different from the dielectric liner 61 and the STI regions 96. In some embodiments, the material of the hard mask layer 73 is chosen to provide high etching selectivity from the material of the STI regions 96, such that in a subsequent sheet formation process (e.g., an etching process shown in FIGS. 20A and 20B) to form nanostructures (e.g., nanosheets), the hard mask layer 73 protects the STI regions 96 to prevent loss of the STI regions 96. In an embodiment, the STI regions 96 is formed of silicon oxide, and the hard mask layer 73 is formed of silicon nitride. Besides silicon nitride, other suitable materials, such as silicon oxynitride, silicon oxycarbonitride, or the like, may also be used for the hard mask layer 73. A suitable formation method, such as CVD, plasma-enhanced CVD (PECVD), or the like, may be used to form the hard mask layer 73.

In some embodiments, the hard mask layer 73 is formed to have a non-uniform thickness. For example, the horizontal portions of the hard mask layer 73 (e.g., portions over the top surfaces of the fin structures 91 and/or over the top surfaces of the STI regions 96) have a thickness T2, the vertical portions of the hard mask layer 73 (e.g., portions on the sidewalls of the fin structures 91) have a thickness T1, and the thickness T2 is larger than the thickness T1. In an embodiment, the thickness T1 may be in a range from 0.5 nm to 4 nm, and the thickness T2 may be in a range from 10 nm to 25 nm.

In some embodiments, the hard mask layer 73 with non-uniform thickness is formed by a PECVD process disclosed herein. The PEVCD process includes multiple deposition cycles, where each deposition cycle includes a plurality of processing steps performed in a process chamber. In some embodiments, the plurality of processing steps in a deposition cycle includes a first processing step, a second processing step, and a third processing step performed sequentially. After each of the first, the second, and the third processing steps, the un-used precursors, the plasma generated during the processing step, and/or the by-product(s) of the processing step (if any), are evacuated from the process chamber by, e.g., a vacuuming mechanism. For ease of discussion, the layer of material formed after completion of each deposition cycle of the PECVD process is referred to as a sublayer of the hard mask layer 73.

In some embodiments, the first processing step in a deposition cycle is a plasma process that forms a layer of silicon on the underlying layer (e.g., the dielectric liner 61, or a previously formed sublayer of the hard mask layer 73). In an example embodiment, a gas source comprising a silicon-containing precursor (e.g., silane (SiH₄)) is supplied to the process chamber. A radio-frequency (RF) power source is turned on to ignite the gas source into a plasma. The plasma energy breaks down the precursor molecules into reactive species, and the reactive species diffuse to the underlying layer and react to form the layer of silicon. In some embodiments, an etching gas (e.g., H₂) is included in the gas source with the silicon-containing precursor. During the first processing step, the plasma of the etching gas (e.g., plasma of H₂) etches the silicon layer, and may help to control (e.g., slow down) the growth rate of the silicon layer and to achieve better control of the profile of the silicon layer. After the first processing step, un-used precursor, etching gas, plasma, and/or by-product(s) (if any) are evacuated from the process chamber.

In some embodiments, the second processing step in a deposition cycle is a plasma process (e.g., a plasma etching process) that adjusts (e.g., modifies, changes) the thicknesses of the horizontal portions (e.g., portions over the top surfaces of the fin structures 91, and over the top surfaces of the STI regions 96) of the silicon layer and the vertical portions (e.g., portions on the sidewalls of the fin structures 91) of the silicon layer formed in the first processing step. In an example embodiment, the plasma processing increases a ratio between the thickness of the horizontal portions of the silicon layer and the thickness of the vertical portions of the silicon layer. The plasma process (e.g., a plasma etching process) achieves the adjustment by adjusting the ratio between the vertical etching rate and the horizontal etching rate of the plasma process, as an example. By adjusting the process conditions of the plasma process, such as the pressure, the temperature, the power of the RF power source, and/or the duration of the plasma process, the ratio between the vertical etching rate and the horizontal etching rate are adjusted. For example, the horizontal etching rate may be adjusted to be higher than the vertical etching rate, such that the ratio between the thickness of the horizontal portions of the silicon layer and the thickness of the vertical portions of the silicon layer is decreased after the plasma process of the second processing step.

In some embodiments, the plasma process of the second processing step is performed using a gas source comprising hydrogen gas (H₂). The gas source is ignited into a plasma by the RF power source, and the H₂ plasma etches the silicon layer formed in the first processing step. Therefore, the second processing step may also be referred to as a hydrogen plasma etching process or hydrogen plasma treatment of the silicon layer. After the second processing step, un-used etching gas, plasma, and/or by-product(s) (if any) are evacuated from the process chamber.

In some embodiments, the third processing step in a deposition cycle is a plasma process performed to nitridize the silicon layer into a silicon nitride layer, and therefore, may also be referred to as a nitridation process. In some embodiments, the plasma process of the third processing step is performed using a gas source comprising nitrogen gas (N₂). The gas source is ignited into a plasma by the RF power source, and the N₂ plasma reacts with the silicon layer and turns the silicon layer into a silicon nitride layer. Therefore, after the third processing step, a sublayer of the hard mask layer 73 (e.g., a sublayer of silicon nitride) is formed. After the third processing step, un-used gas source, plasma, and/or by-product(s) (if any) are evacuated from the process chamber. The above described deposition cycle is repeated, until the thickness of the hard mask layer 73 reaches a target value.

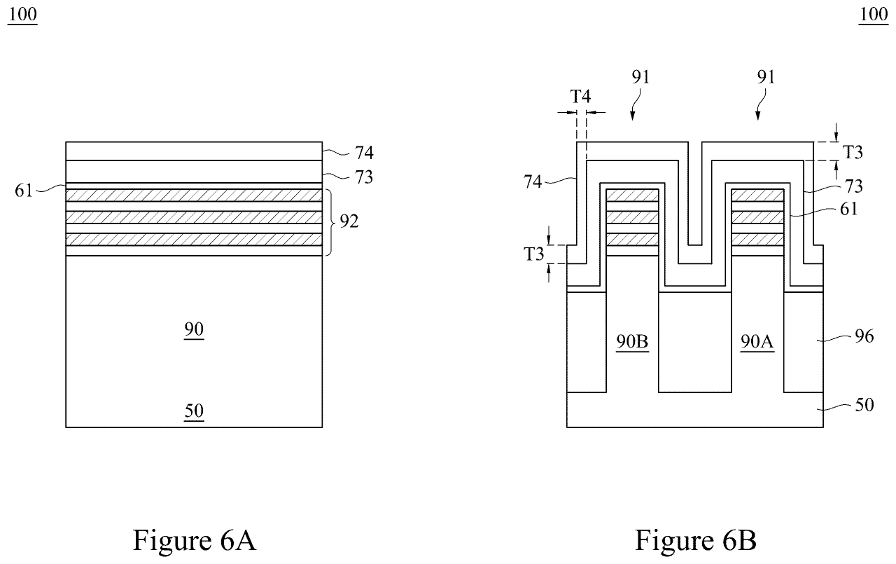

In FIGS. 6A and 6B, a capping layer 74 is formed over the hard mask layer 73. The capping layer 74 may be formed of a material different from the hard mask layer 73. In an embodiment, the capping layer 74 may comprise an oxide, such as silicon oxide, or the like. A suitable formation method, such as CVD, plasma-enhanced CVD (PECVD), or the like, may be used to form the capping layer 74.

In some embodiments, the capping layer 74 is formed to have a non-uniform thickness. For example, the horizontal portions of the capping layer 74 (e.g., portions over the top surfaces of the fin structures 91 and over the top surfaces of the STI regions 96) have a thickness T3, the vertical portions of the capping layer 74 (e.g., portions on the sidewalls of the fin structures 91) have a thickness T4, and the thickness T3 is larger than the thickness T4. In an embodiment, the thickness T3 may be equal to or smaller than 2 nm, such as in a range from 1 nm to 2 nm. In an embodiment, the thickness T4 may be equal to or smaller than 0.5 nm, such as in a range from 0.2 nm to 0.5 nm.

In some embodiments, the capping layer 74 with non-uniform thickness is formed by a PECVD process disclosed herein. The PEVCD process includes multiple deposition cycles, where each deposition cycle includes a plurality of processing steps performed in a process chamber. In some embodiments, the process chamber may be the same process chamber described in FIGS. 5A and 5B that was used to form the hard mask layer 73. In some embodiments, the plurality of processing steps in a deposition cycle includes a fourth processing step, a fifth processing step, and a sixth processing step performed sequentially. After each of the fourth, the fifth, and the sixth processing steps, the un-used precursors, the plasma generated during the processing step, and/or the by-product(s) of the processing step (if any), are evacuated from the process chamber by, e.g., a vacuuming mechanism. For ease of discussion, the layer of material formed after completion of each deposition cycle of the PECVD process is referred to as a sublayer of the capping layer 74.

In some embodiments, the fourth processing step in a deposition cycle may be performed in a similar manner and using similar materials as the first processing step that was described previously in FIGS. 5A and 5B.

In some embodiments, the fifth processing step in a deposition cycle may be performed in a similar manner and using similar materials as the second processing step that was described previously in FIGS. 5A and 5B. In some embodiments, the fifth processing step in a deposition cycle is a plasma process (e.g., a plasma etching process) that adjusts (e.g., modifies, changes) the thicknesses of the horizontal portions (e.g., portions over the top surfaces of the fin structures 91, and over the top surfaces of the STI regions 96) of the silicon layer and the vertical portions (e.g., portions on the sidewalls of the fin structures 91) of the silicon layer formed in the fourth processing step. In an example embodiment, the plasma processing increases a ratio between the thickness of the horizontal portions of the silicon layer and the thickness of the vertical portions of the silicon layer. The plasma process (e.g., a plasma etching process) achieves the adjustment by adjusting the ratio between the vertical etching rate and the horizontal etching rate of the plasma process, as an example. By adjusting the process conditions of the plasma process, such as the pressure, the temperature, the power of the RF power source, and/or the duration of the plasma process, the ratio between the vertical etching rate and the horizontal etching rate are adjusted. For example, the horizontal etching rate may be adjusted to be higher than the vertical etching rate, such that the ratio between the thickness of the horizontal portions of the silicon layer and the thickness of the vertical portions of the silicon layer is decreased after the plasma process of the fifth processing step.

In some embodiments, the plasma process of the fifth processing step is performed using a gas source comprising hydrogen gas (H₂). The gas source is ignited into a plasma by the RF power source, and the H₂ plasma etches the silicon layer formed in the fourth processing step. Therefore, the fifth processing step may also be referred to as a hydrogen plasma etching process or hydrogen plasma treatment of the silicon layer. After the fifth processing step, un-used etching gas, plasma, and/or by-product(s) (if any) are evacuated from the process chamber.

In some embodiments, the sixth processing step in a deposition cycle is a plasma process performed to oxidize the silicon layer into a silicon oxide layer, and therefore, may also be referred to as an oxidation process. In some embodiments, the plasma process of the sixth processing step is performed using a gas source comprising nitrous oxide (N₂O) gas. The gas source is ignited into a plasma by the RF power source, and the N₂O plasma reacts with the silicon layer and turns the silicon layer into a silicon oxide layer. Therefore, after the sixth processing step, a sublayer of the capping layer 74 (e.g., a sublayer of silicon oxide) is formed. After the sixth processing step, un-used gas source, plasma, and/or by-product(s) (if any) are evacuated from the process chamber. The above described deposition cycle is repeated, until the thickness of the capping layer 74 reaches a target value.

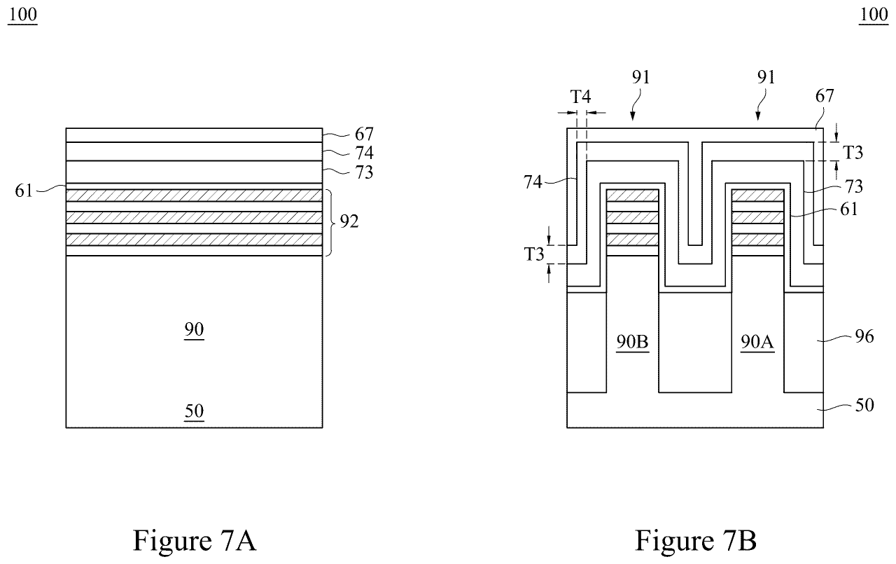

Next, in FIGS. 7A and 7B, a mask layer 67 is formed over the capping layer 74. In some embodiments, the mask layer 67 is a Bottom Anti-Reflective Coating (BARC) layer typically used in a tri-layered photoresist. The BARC layer may be a carbon-containing material, such as spin-on glass (SOG) carbon, as an example. In other embodiments, the BARC layer may comprise a material such as carbon, Silicon oxide, or the like. Therefore, the mask layer 67 may also be referred to as a BARC layer 67 in the discussion herein, with the understanding that other suitable materials may also be used. As illustrated in FIGS. 7A and 7B, the BARC layer 67 fills the trenches between adjacent fin structures 91, and covers the top surfaces of the fin structures 91.

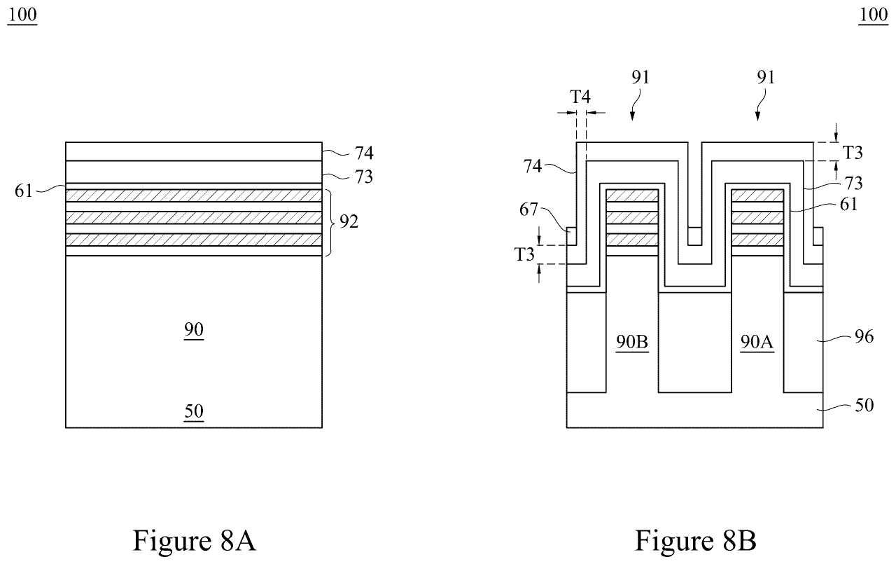

Next, in FIGS. 8A and 8B, the BARC layer 67 is etched back using a first etching process to expose top portions of the capping layer 74 that are disposed on sidewalls of the fin structures 91 and over the fin structures 91. The top portions of the capping layer 74 may be disposed above a top surface of the etched-back BARC layer 67. The first etching process may be a suitable etching process, such as a dry etching process, a wet etching process, combinations thereof, or the like, that is performed to etch back the BARC layer 67. The first etching process may be a timed process to etch back the BARC layer 67 by a pre-determined amount. In some embodiments, the first etching process is performed using an etchant selective to (e.g., having a higher etching rate for) the material of the BARC layer 67, such that the BARC layer 67 is removed without substantially attacking the capping layer 74. After the BARC layer 67 is etched back, the top surface of the BARC layer 67 may be disposed between a topmost surface of the layer stack 92 and a bottommost surface of the layer stack 92. In an embodiment, after the BARC layer 67 is etched back, the BARC layer 67 partially fills the trenches between adjacent fin structures 91.

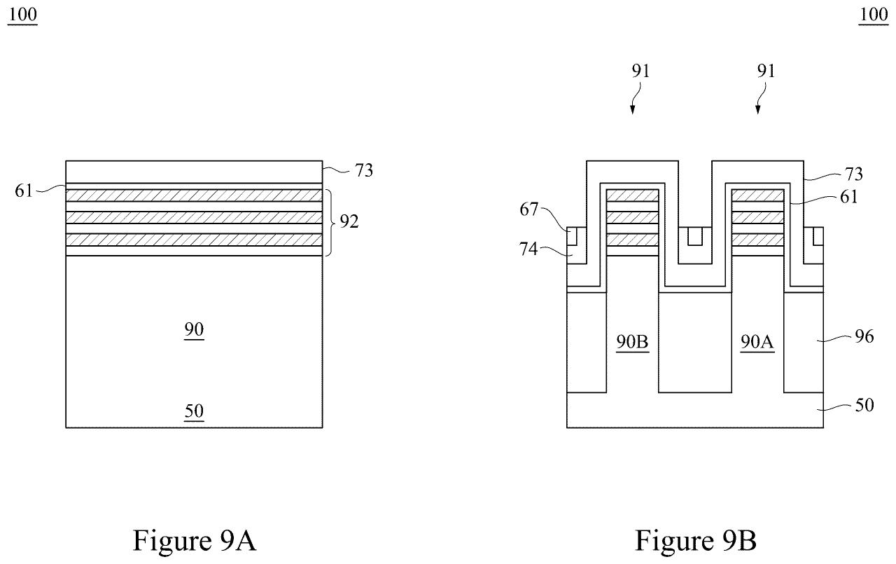

In FIGS. 9A and 9B, the exposed top portions of the capping layer 74 are removed by a second etching process. For example, the second etching process may be a wet etching process or a dry etching process that is performed using a fluorine-based etchant. In an embodiment, the second etching process may be a dry etching process that is performed using, e.g., a gas source comprising a fluorine-based etching gas. The gas source may include hydrogen fluoride (HF), as an example. In an embodiment, the second etching process may be a wet etching process that is performed using hydrogen fluoride (HF) as an etchant. In the illustrated example of FIGS. 9A and 9B, the second etching process exposes top portions of the hard mask layer 73 that are disposed on sidewalls of the fin structures 91 and over the fin structures 91. The top portions of the hard mask layer 73 may be disposed above the top surface of the etched-back BARC layer 67. Due to the etching selectivity between the capping layer 74 and the BARC layer 67/the hard mask layer 73, the BARC layer 67/the hard mask layer 73 remains substantially un-etched.

In FIGS. 10A and 10B, the remaining portions of the BARC layer 67 are removed by an etching process. The etching process may be dry etching, wet etching, combinations thereof, or the like. In some embodiments, the etching process is a plasma etching process performed using a gas source comprising H₂ and N₂ gases. After the removal of the remaining portions of the BARC layer 67, remaining portions of the capping layer 74 that were underlying the remaining portions of the BARC layer 67 are exposed. The remaining portions of the capping layer 74 include vertical portions on the sidewalls of the fin structures 91, and horizontal portions over the STI region 96.

After performing the etching process to remove the remaining portions of the BARC layer 67, a cleaning process may be performed that exposes surfaces of the NSFET device 100 to a mixture of deionized water, hydrogen peroxide (H₂O₂), and ammonium hydroxide (NH₄OH), in order to remove contaminants, particles, and/or impurities.

Referring further to FIGS. 10A and 10B, after performing the cleaning process, a third etching process is performed to remove the exposed top portions of the hard mask layer 73 that are disposed on sidewalls of the fin structures 91 and over the fin structures 91. The top portions of the hard mask layer 73 may be disposed above a topmost point of the capping layer 74. The third etching process may comprise a dry etching process, a wet etching process, combinations thereof, or the like. In an embodiment, performing the third etching process may comprise performing a wet etching process using phosphoric acid (H₃PO₄) as an etchant. Due to the etching selectivity between the capping layer 74 and the hard mask layer 73, the capping layer 74 remains substantially un-etched, and protects the unexposed bottom portions of the hard mask layer 73 that underlie the capping layer 74 from being etched during the third etching process. After the third etching process is performed, top portions of the dielectric liner 61 that are disposed on sidewalls of the fin structures 91 and over the fin structures 91 are exposed. The top portions of the dielectric liner 61 may be disposed above topmost points of the capping layer 74 and the hard mask layer 73.

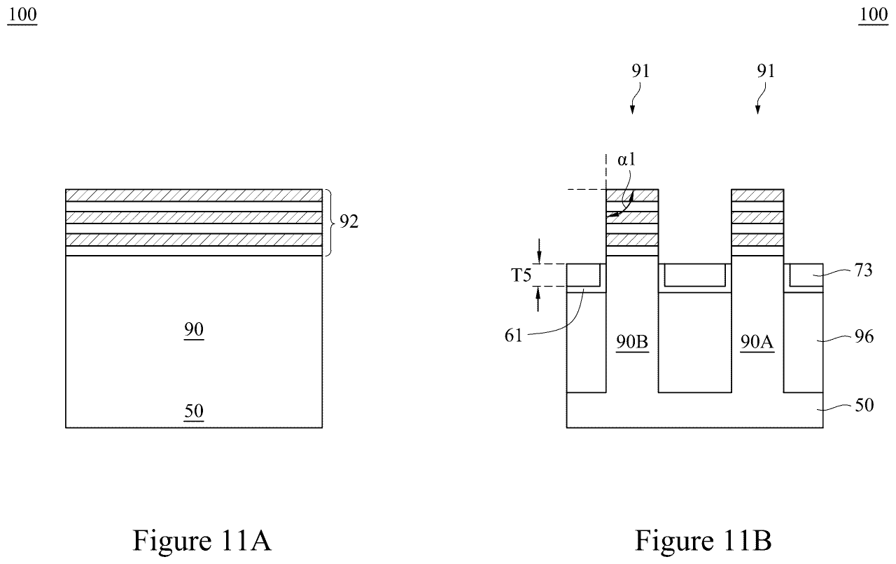

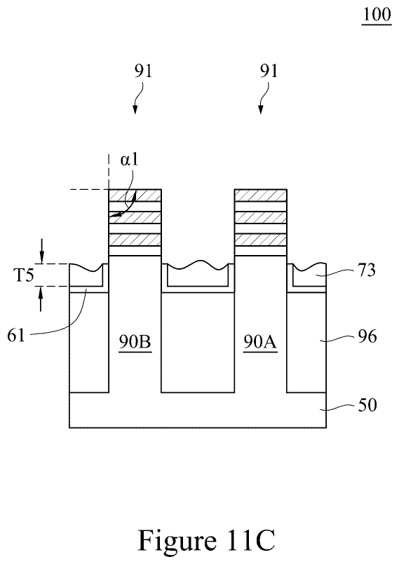

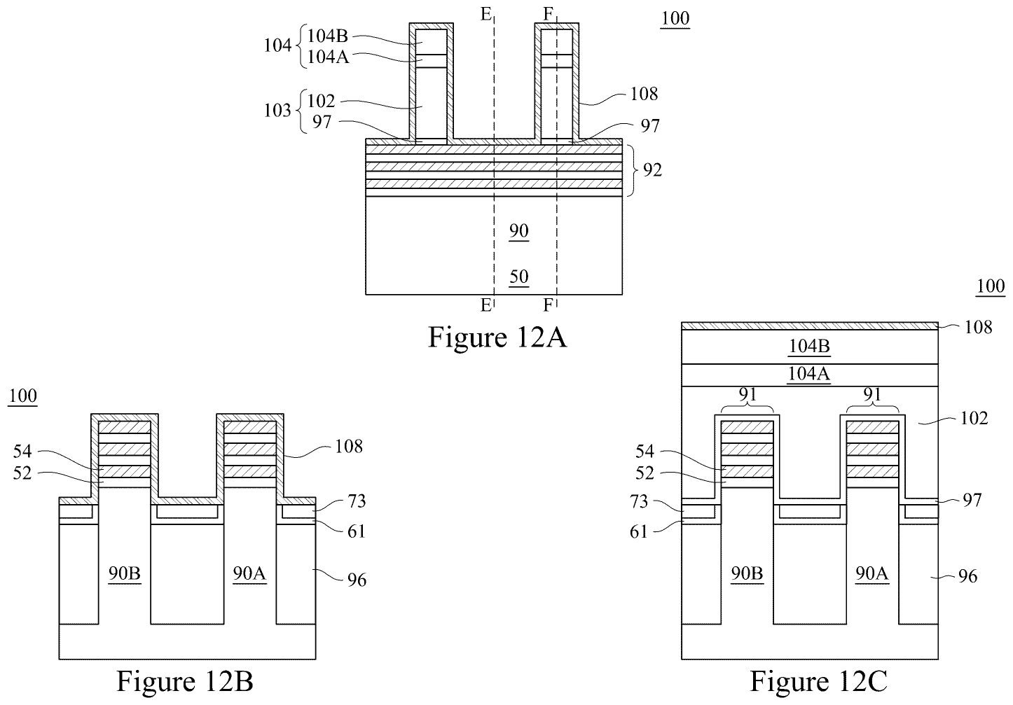

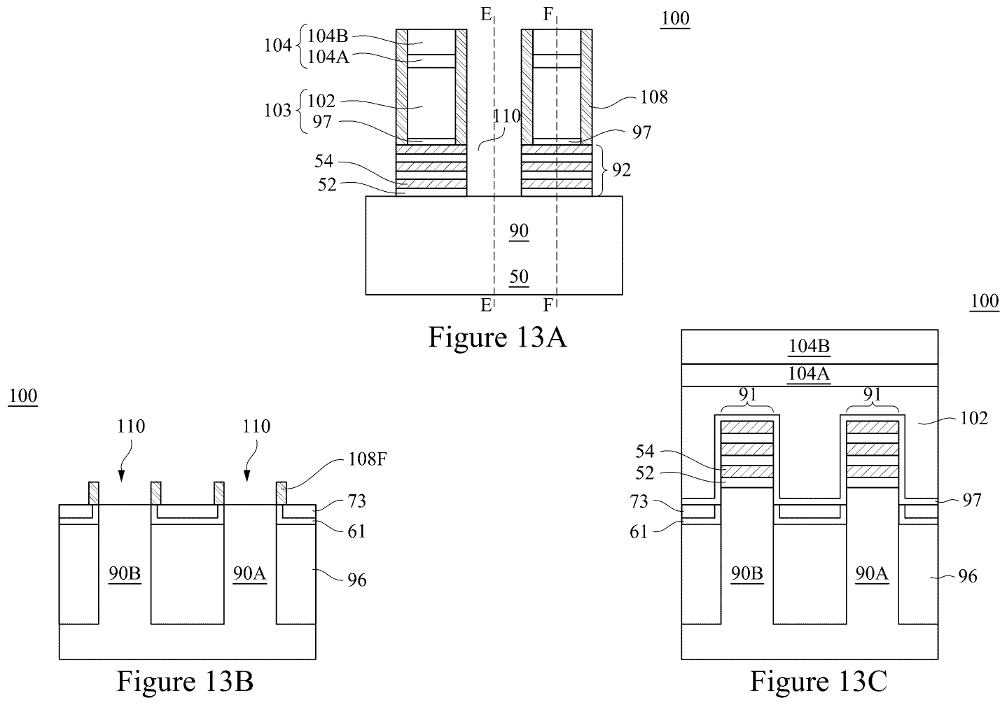

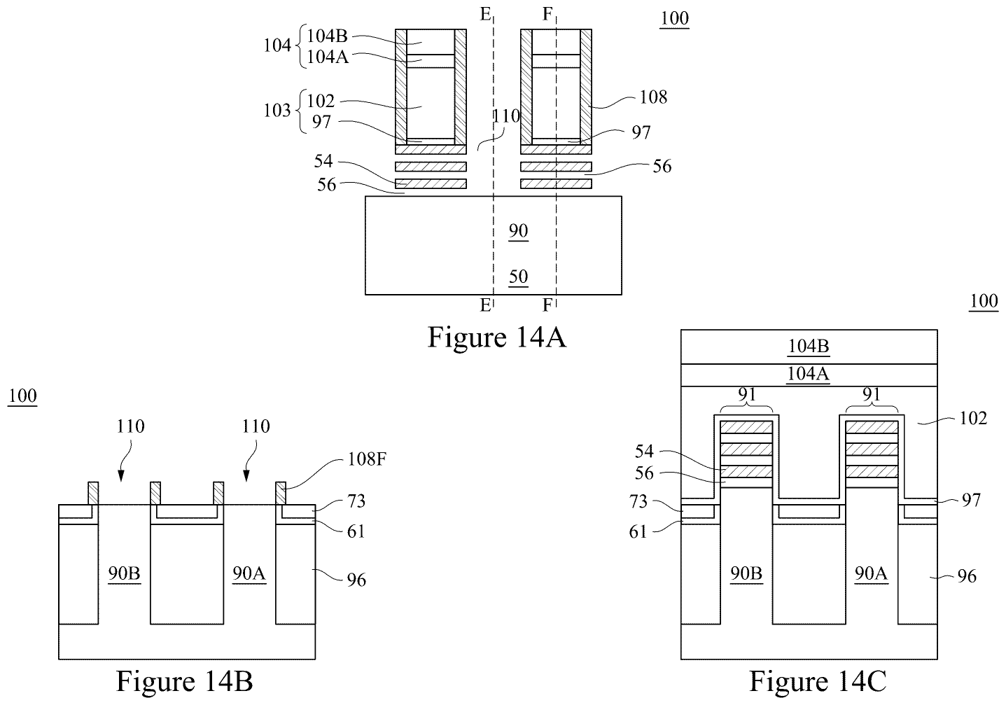

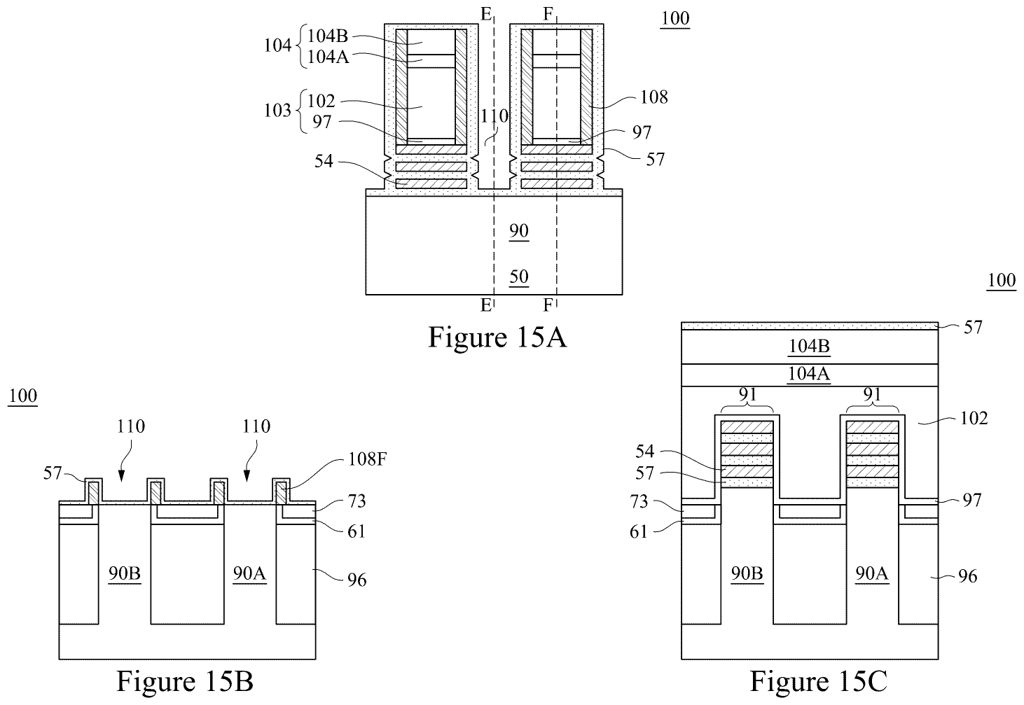

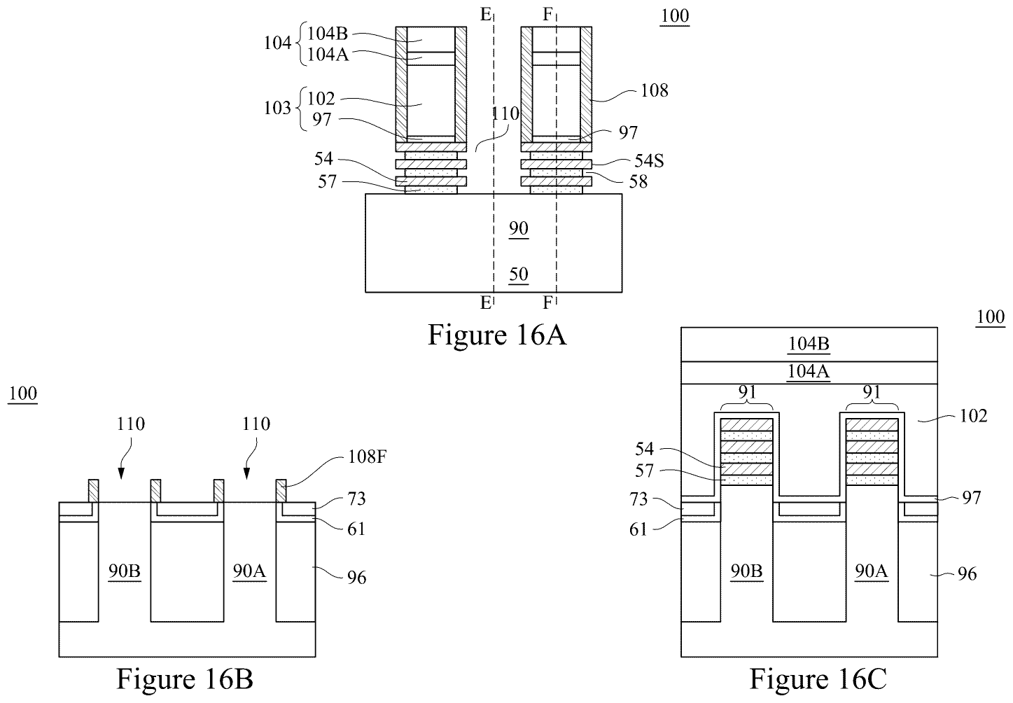

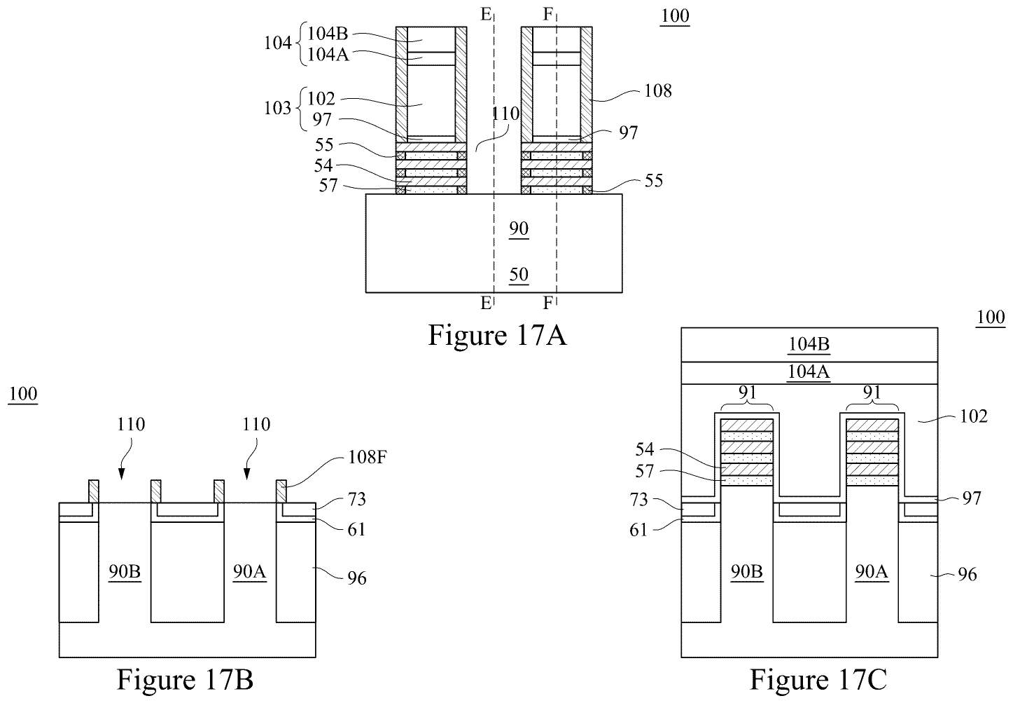

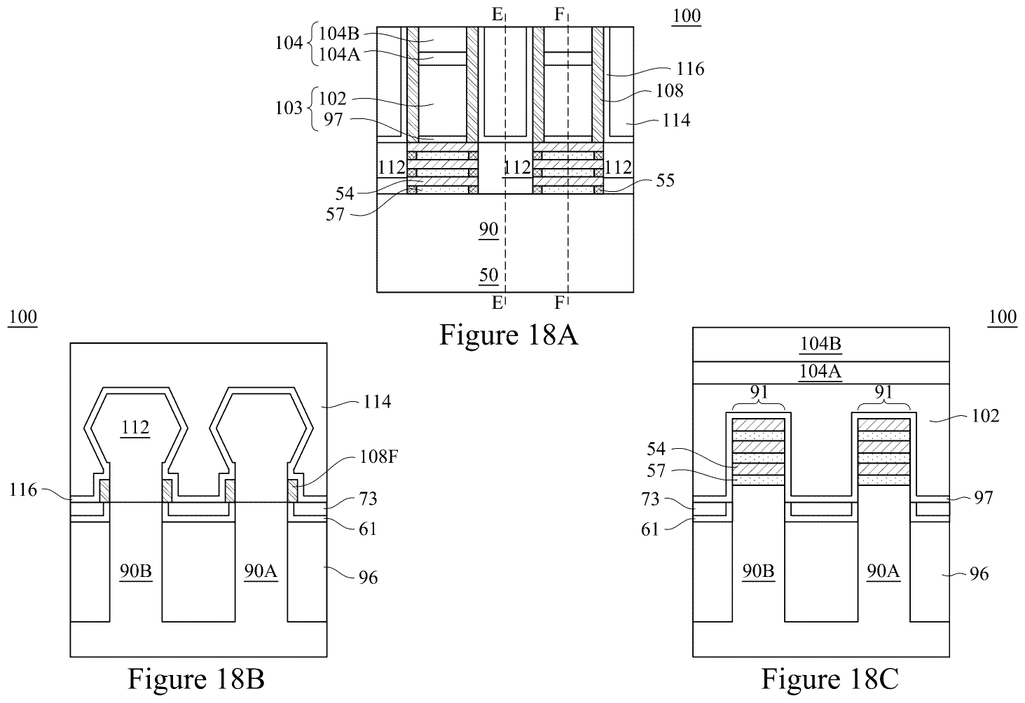

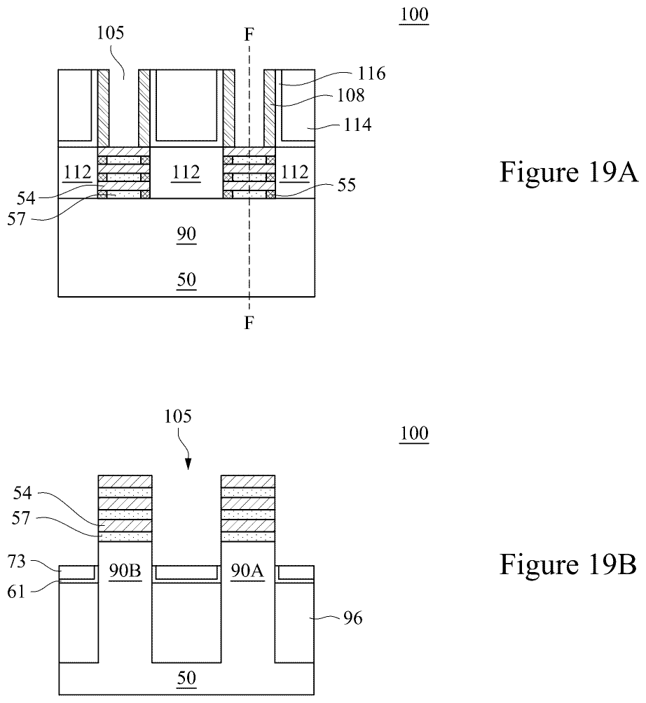

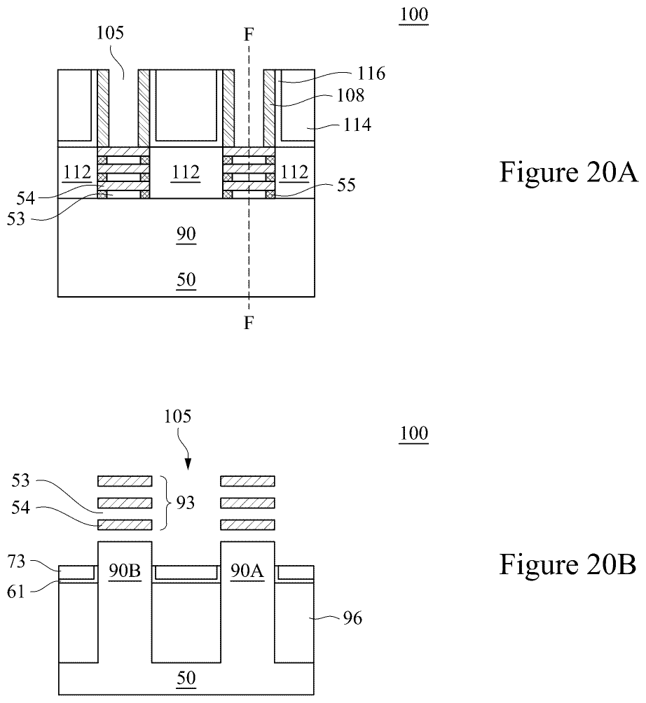

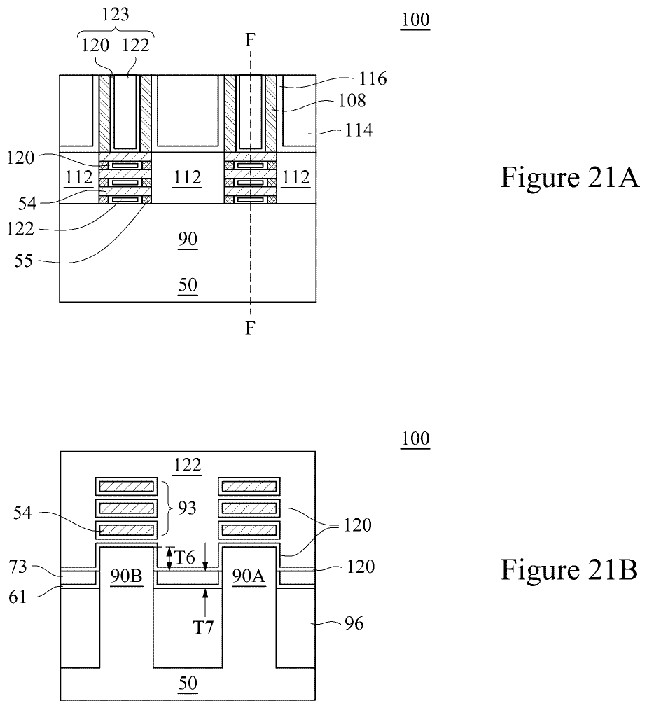

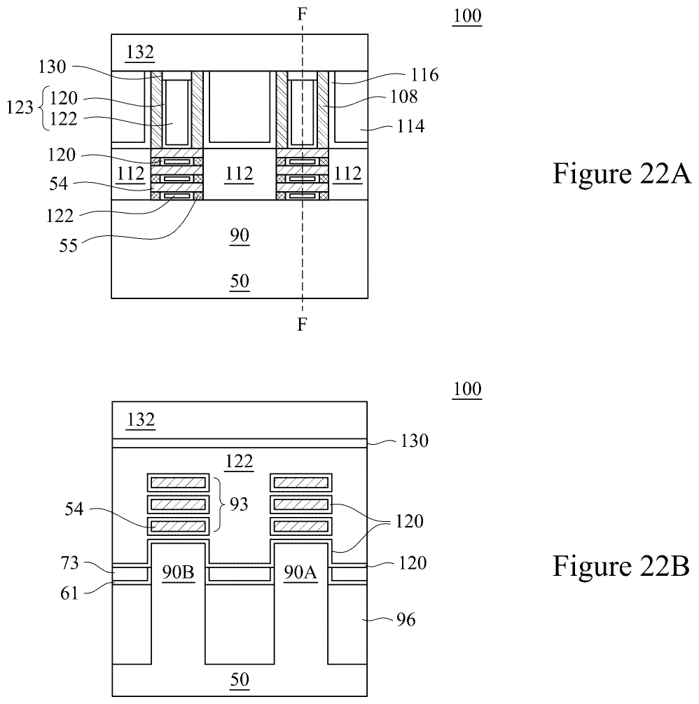

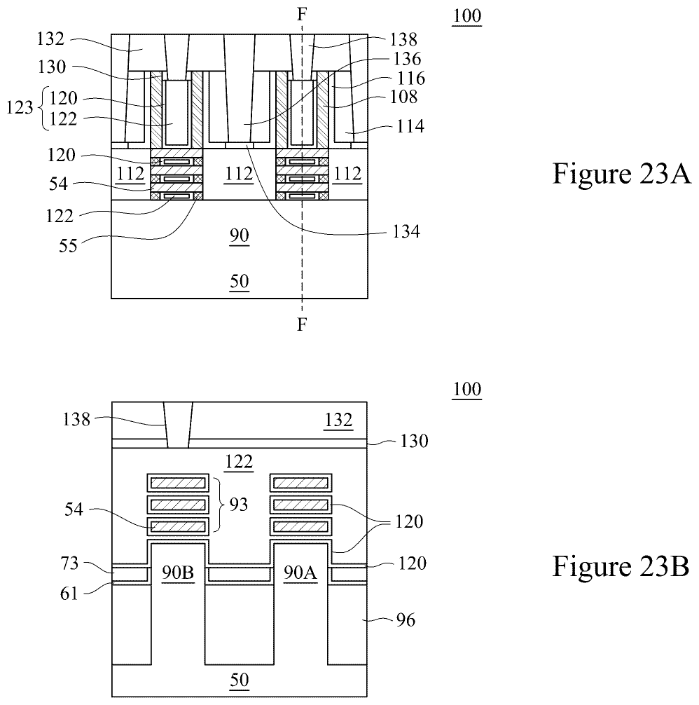

Advantages can be achieved by forming the capping layer 74 having a non-uniform thickness over the hard mask layer 73 and the dielectric liner 61, wherein the horizontal portions of the capping layer 74 (e.g., portions over the top surfaces of the fin structures 91 and over the top surfaces of the STI regions 96) have a thickness T3, the vertical portions of the capping layer 74 (e.g., portions on the sidewalls of the fin structures 91) have a thickness T4, and the thickness T3 is larger than the thickness T4. In an embodiment, the thickness T3 may be equal to or smaller than 2 nm, such as in a range from 1 nm to 2 nm. In an embodiment, the thickness T4 may be equal to or smaller than 0.5 nm, such as in a range from 0.2 nm to 0.5 nm. These advantages include the capping layer 74 reducing a risk of unwanted etching of the underlying hard mask layer 73 during subsequent etching processes (e.g., the first etching process, the third etching process, and a fourth etching process (described subsequently in FIGS. 11A and 11B). As a result, a thickness loss of the thickness T2 of the horizontal portions of the hard mask layer 73 (e.g., portions over the top surfaces of the fin structures 91 and/or over the top surfaces of the STI regions 96), and the thickness T1 of the vertical portions of the hard mask layer 73 (e.g., portions on the sidewalls of the fin structures 91) can be minimized. In addition, a uniform thickness of the hard mask layer 73 can be achieved over the top surfaces of the fin structures 91, as well as over the STI regions 96. For example, the horizontal portions of the hard mask layer 73 that are disposed over the top surfaces of the fin structures 91 that have a reduced thickness (e.g., as a result unwanted etching during the first etching process) that is smaller than the thickness T2 and that have thickness non-uniformities would increase a risk of etching damage and rounding of top corners of the layer stack 92 (e.g., that include subsequently formed channel layers) during subsequent etching processes (e.g., the third etching process) that may be performed to remove top portions of the hard mask layer 73 that are disposed over the fin structures 91. By reducing these thickness non-uniformities of the hard mask layer 73 and preventing unwanted etching that may significantly reduce the thickness of the horizontal portions of the hard mask layer 73, a risk of etching damage and rounding of the top corners of the layer stack 92 (e.g., that include subsequently formed channel layers) during subsequent etching processes (e.g., the third etching process) is reduced. As a result, device characteristics and performance can be preserved, and device reliability is increased.

Additional advantages can also be achieved by forming the capping layer 74 over the hard mask layer 73 and the dielectric liner 61, where the capping layer 74 reduces or prevents unwanted etching (e.g., during the third etching process and the fourth etching process (described below in FIGS. 11A and 11B) that may significantly reduce the thickness of the horizontal portions of the hard mask layer 73 over the STI regions 96. These advantages include that during a subsequent selective etching process (described in FIGS. 20A and 20B) that is used to release the second semiconductor material 54 to form nanostructures 54 of the NSFET device 100, the hard mask layer 73 over the STI regions 96 may have a suitable thickness to be able to provide increased protection to portions of the STI regions 96 from the selective etching process, and therefore, prevents or reduces loss of the STI regions 96 due to the selective etching process. As a result, device reliability can be improved.

In FIGS. 11A and 11B, the fourth etching process is performed to remove the remaining portions of the capping layer 74, portions of the hard mask layer 73 on sidewalls of the fin structures 91, and portions of the dielectric liner 61 that are disposed on sidewalls of the fin structures 91 and over the fin structures 91. The fourth etching process may comprise a dry etching process, a wet etching process, combinations thereof, or the like. For example, performing the fourth etching process may comprise performing a wet etching process using hydrofluoric acid (HF) as an etchant. After the fourth etching process, remaining portions of the dielectric liner 61 and the remaining portions of the hard mask layer 73 are disposed in the trenches between adjacent fin structures 91, wherein a topmost surface of the dielectric liner 61 and a topmost surface of the hard mask layer 73 are level. As illustrated in FIGS. 11A and 11B, the dielectric liner 61 and the hard mask layer 73 cover and extend along the upper surfaces of the STI regions 96. The dielectric liner 61 and the hard mask layer 73 protect (e.g., shield) the STI regions 96 in a subsequent sheet formation process (described in FIGS. 20A and 20B) to prevent or reduce loss of the STI regions 96.

As illustrated in FIGS. 11A and 11B, the dielectric liner 61 extends along sidewalls and a bottom surface of the hard mask layer 73. In some embodiments, an upper surface of the hard mask layer 73 is a flat surface, as illustrated in FIG. 11B. In some embodiments, the upper surface of the hard mask layer 73 may be a curved surface, such as for example, a convex surface. In an embodiment, the upper surface of the hard mask layer 73 may have a wavy or undulating surface, as shown in FIG. 11C. Subsequent drawings use the example where the hard mask layer 73 has a flat surface, with the understanding that the upper surface of the hard mask layer 73 may have other shapes, such as a convex surface or a wavy surface. These and other variations are fully intended to be included within the scope of the present disclosure.

In an embodiment, after the fourth etching process is performed, an angle α1 between a top surface of the fin structure 91 and a sidewall of the fin structure 91 is in a range from 80 degrees to 100 degrees. In an embodiment, after the fourth etching process is performed, the hard mask layer 73 may have a thickness T5. In an embodiment, a difference between the thickness T2 (shown previously in FIG. 5B) of the horizontal portions of the hard mask layer 73 (e.g., portions over the top surfaces of the STI regions 96) and the thickness T5 of the horizontal portions of the hard mask layer 73 (e.g., portions over the top surfaces of the STI regions 96) is less than 1.5 nm. In an embodiment, the thickness T2 is larger than the thickness T5.

Next, in FIGS. 12A-12C, a dummy dielectric layer is formed over the hard mask layer 73, the dielectric liner 61, and over sidewalls and top surfaces of the fin structures 91. The dummy dielectric layer may be, for example, silicon oxide, silicon nitride, a combination thereof, or the like, and may be deposited or thermally grown according to acceptable techniques. In an embodiment, a layer of silicon is conformally formed over sidewalls and top surfaces of the layer stack 92 and over upper surfaces of the hard mask layer 73 and the dielectric liner 61, and a thermal oxidization process is performed to convert the deposited silicon layer into an oxide layer as the dummy dielectric layer.

Next, dummy gates 102 are formed over the fin structures 91. To form the dummy gates 102, a dummy gate layer may be formed over the dummy dielectric layer. The dummy gate layer may be deposited over the dummy dielectric layer and then planarized, such as by a CMP. The dummy gate layer may be a conductive material and may be selected from a group including amorphous silicon, polycrystalline-silicon (polysilicon), poly-crystalline silicon-germanium (poly-SiGe), or the like. The dummy gate layer may be deposited by physical vapor deposition (PVD), CVD, sputter deposition, or other techniques known and used in the art.

Masks 104 are then formed over the dummy gate layer. The masks 104 may be formed from silicon nitride, silicon oxynitride, combinations thereof, or the like, and may be patterned using acceptable photolithography and etching techniques. In the illustrated embodiment, the mask 104 includes a first mask layer 104A (e.g., a silicon oxide layer) and a second mask layer 104B (e.g., a silicon nitride layer). The pattern of the masks 104 is then transferred to the dummy gate layer by an acceptable etching technique to form the dummy gates 102, and then transferred to the dummy dielectric layer by acceptable etching technique to form dummy gate dielectric 97. The dummy gates 102 cover respective channel regions of the layer stacks 92. The pattern of the masks 104 may be used to physically separate each of the dummy gates 102 from adjacent dummy gates. The dummy gates 102 may also have a lengthwise direction substantially perpendicular to the lengthwise direction of the fin structures 91. The dummy gate 102 and the corresponding dummy gate dielectric 97 may be collectively referred to as a dummy gate structure 103.

Next, a gate spacer layer 108 is formed by conformally depositing an insulating material over the layer stacks 92, the hard mask layer 73, the dielectric liner 61, and the dummy gate structures 103. The insulating material may be silicon nitride, silicon carbonitride, a combination thereof, or the like. In some embodiments, the gate spacer layer 108 includes multiple sublayers. For example, a first sublayer (sometimes referred to as a gate seal spacer layer) may be formed by thermal oxidation or a deposition, and a second sublayer (sometimes referred to as a main gate spacer layer) may be conformally deposited on the first sublayer.

FIGS. 12B and 12C illustrate cross-sectional views of the NSFET device 100 in FIG. 12A along cross-sections E-E and F-F in FIG. 12A, respectively. The cross-sections E-E and F-F correspond to cross-sections D-D and A-A in FIG. 1, respectively. Note that FIG. 12A illustrates the cross-sectional view along the longitudinal direction (e.g., a current flow direction) of one of the fins 90, the cross-sectional views along the longitudinal directions (e.g., current flow directions) of other fins 90 are the same or similar unless otherwise specified. In addition, FIG. 12A illustrates two dummy gate structures 103 as a non-limiting example, the number of dummy gate structures 103 over the fins 90 may be any suitable number.

Next, in FIGS. 13A-13C, the gate spacer layer 108 is etched by an anisotropic etching process to form gate spacers 108. The anisotropic etching process may remove horizontal portions of the gate spacer layer 108 (e.g., portions over the hard mask layer 73 and the dummy gate structures 103), with remaining vertical portions of the gate spacer layer 108 along sidewalls of the dummy gates 102 and the dummy gate dielectric 97 forming the gate spacers 108. In addition, the remaining vertical portions of the gate spacer layer 108 along sidewalls of the fins 90 form fin spacers 108F (see, e.g., FIG. 13B).

After the formation of the gate spacers 108, implantation for lightly doped source/drain (LDD) regions (not shown) may be performed. Appropriate type (e.g., p-type or n-type) impurities may be implanted into the exposed layer stacks 92 and/or semiconductor fins 90. The n-type impurities may be any suitable n-type impurities, such as phosphorus, arsenic, antimony, or the like, and the p-type impurities may be any suitable p-type impurities, such as boron, BF₂, indium, or the like. The lightly doped source/drain regions may have a concentration of impurities of from about 10¹⁵ cm⁻³ to about 10¹⁶ cm⁻³. An anneal process may be used to activate the implanted impurities.

Next, openings 110 (which may also be referred to as recesses or source/drain openings) are formed in the layer stacks 92. The openings 110 may extend through the layer stacks 92 and into the fins 90. The openings 110 may be formed by an anisotropic etching process such as RIE, NBE, or the like, using, e.g., the dummy gates 102 and the gate spacers 108 as an etching mask. Sidewalls of the openings 110 expose the first semiconductor material 52 and the second semiconductor material 54. As illustrated in FIG. 13B, top surfaces of the hard mask layer 73 and the dielectric liner 61 (e.g., and top surfaces of the fins 90) may be level with bottom surfaces of the openings 110. In some embodiments, the bottom surfaces of the openings 110 are disposed below the top surfaces of the hard mask layer 73 and the dielectric liner 61.

Next, in FIGS. 14A-14C, the first semiconductor material 52 under the dummy gates 102 and exposed by the openings 110 are removed. The first semiconductor material 52 may be removed by performing an isotropic etching process such as wet etching or the like using etchant(s) which is selective to the materials of the first semiconductor material 52, while the second semiconductor material 54, the fins 90, and the hard mask layer 73 remain relatively unetched as compared to the first semiconductor material 52. In embodiments in which the first semiconductor material 52 include, e.g., SiGe, and the second semiconductor material 54 include, e.g., Si or SiC, tetramethylammonium hydroxide (TMAH), ammonium hydroxide (NH₄OH), or the like may be used to selectively remove the first semiconductor material 52. After the first semiconductor material 52 is removed, gaps 56 (e.g., empty spaces) are formed between adjacent layers of the second semiconductor material 54, and between the fin 90 and a lowermost layer of the second semiconductor material 54.

Next, in FIGS. 15A-15C, a disposable material 57 (which may also be referred to subsequently as a sacrificial material) is deposited in the openings 110 to line the sidewalls and bottom surfaces of the openings 110. The disposable material 57 also fills the gaps 56. The disposable material 57 may be deposited by a conformal deposition process, such as CVD, ALD, or the like. The disposable material 57 may be a dielectric material. In some embodiments, the disposable material 57 includes one or more layers of silicon oxide (SiO), silicon oxynitride (SiON), aluminum oxide (Al₂O₃), or the like. These materials are selected for their properties, such as etching selectivity, which allows for precise removal during the manufacturing process without adversely affecting the adjacent and underlying structures. The choice of the disposable material 57 may depend on the specific requirements of the semiconductor device being fabricated and the desired electrical and physical properties of the final product.

Next, in FIGS. 16A-16C, the disposable material 57 disposed outside the gaps 56 are removed, and sidewalls of the remaining portions of the disposable material 57 are recessed from respective sidewalls 54S of the second semiconductor material 54 to form sidewall recesses 58.

In some embodiments, an anisotropic etching process, e.g. a dry etching process such as a plasma etching process, is performed to remove the disposable material 57 disposed outside the gaps 56. Next, an isotropic etching process, such as a wet etching process, is performed to recess the remaining portions of the disposable material 57 to form the sidewall recesses 58. The dry etching process and the wet etching process may use etchants selective to the disposable material 57, such that the disposable material 57 is etched without substantially attacking other material(s) and/or structures. In some embodiments, multiple etching cycles, where each etching cycle includes the dry etching process followed by the wet etching process, are performed to remove the disposable material 57 and to form the sidewall recesses 58. The etching cycles are repeated until sidewalls of the disposable material 57 are recessed past sidewalls 54S of the second semiconductor material 54. In some embodiments, the disposable material 57 is etched by a wet etching process using hydrogen fluoride, diluted hydrogen fluoride, another fluorine-based etchant, or the like as an etchant. The wet etching process is performed until sidewalls of the disposable material 57 are recessed past sidewalls 54S of the second semiconductor material 54. The remaining portions of the disposable material 57, which are interposed between layers of the second semiconductor material 54, and between the fins 90 and a lowermost layer of the second semiconductor material 54, may be referred to as disposable oxide interposers (DOIs). In a subsequent sheet formation process (shown in FIGS. 20A-20C), the DOIs are selectively removed to release the layers of the second semiconductor material 54 to form nanostructures 54 (e.g., nanosheets, or nanowires). This process may be referred to as a DOI process.

Next, in FIGS. 17A-17C, inner spacers 55 are formed in the sidewall recesses 58. FIGS. 17B and 17C illustrate cross-sectional views of the NSFET device 100 in FIG. 17A along cross-sections E-E and F-F, respectively. In some embodiments, to form the inner spacers 55, an inner spacer layer is formed (e.g., conformally) in the openings 110. The inner spacer layer also fills the sidewall recesses 58 of the disposable material 57. The inner spacer layer may be a suitable dielectric material, such as silicon carbonitride (SiCN), silicon oxycarbonitride (SiOCN), or the like, formed by a suitable deposition method such as PVD, CVD, ALD, or the like. Next, an etching process, such as an anisotropic etching process, is performed to remove portions of the inner spacer layer disposed outside the sidewall recesses 58 of the disposable material 57. The remaining portions of the inner spacer layer (e.g., portions disposed inside the sidewall recesses 58 of the disposable material 57) form inner spacers 55. Although outer sidewalls of the inner spacers 55 are illustrated as being flush with sidewalls of the second semiconductor material 54, the outer sidewalls of the inner spacers 55 may extend beyond or be recessed from sidewalls of the second semiconductor material 54. Moreover, although the outer sidewalls of the inner spacers 55 are illustrated as being straight in FIG. 17A, the outer sidewalls of the inner spacers 55 may be concave or convex.

Next, in FIGS. 18A-18C, source/drain regions 112 are formed in the openings 110. In the discussion herein, source/drain region(s) may refer to a source or a drain, individually or collectively dependent upon the context. In the illustrated embodiment, the source/drain regions 112 are formed of an epitaxial material(s), and therefore, may also be referred to as epitaxial source/drain regions 112. In some embodiments, the epitaxial source/drain regions 112 are formed in the openings 110 to exert stress in the respective channel regions of the NSFET device formed, thereby improving performance. In some embodiments, the epitaxial source/drain regions 112 are formed such that the dummy gate 102 is disposed between respective neighboring pairs of the epitaxial source/drain regions 112. In some embodiments, the gate spacers 108 are used to separate the epitaxial source/drain regions 112 from the dummy gates 102 by an appropriate lateral distance so that the epitaxial source/drain regions 112 do not short out subsequently formed gates of the resulting NSFET device.

The epitaxial source/drain regions 112 are epitaxially grown in the openings 110. The epitaxial source/drain regions 112 may include any acceptable material, such as appropriate for n-type or p-type device. For example, when n-type devices are formed, the epitaxial source/drain regions 112 may include materials exerting a tensile strain in the channel regions, such as silicon, SiC, SiCP, SiP, or the like. Likewise, when p-type devices are formed, the epitaxial source/drain regions 112 may include materials exerting a compressive strain in the channel regions, such as SiGe, SiGeB, Ge, GeSn, or the like. The epitaxial source/drain regions 112 may have surfaces raised from respective surfaces of the fins 90 and may have facets.

The epitaxial source/drain regions 112 and/or the fins 90 may be implanted with dopants to form source/drain regions, similar to the process previously discussed for forming lightly-doped source/drain regions, followed by an anneal. The source/drain regions may have an impurity concentration of between about 10¹⁹ cm⁻³ and about 10²¹ cm⁻³. The n-type and/or p-type impurities for source/drain regions may be any of the impurities previously discussed. In some embodiments, the epitaxial source/drain regions 112 may be in situ doped during growth.

As a result of the epitaxy processes used to form the epitaxial source/drain regions 112, upper surfaces of the epitaxial source/drain regions 112 have facets which expand laterally outward beyond sidewalls of the fins 90. In some embodiments, adjacent epitaxial source/drain regions 112 over adjacent fins 90 remain separated after the epitaxy process is completed, as illustrated in FIG. 18B. In other embodiments, these facets cause adjacent epitaxial source/drain regions 112 to merge.

Next, a contact etch stop layer (CESL) 116 is formed (e.g., conformally) over the epitaxial source/drain regions 112 and over the dummy gate structures 103, and a first inter-layer dielectric (ILD) 114 is then deposited over the CESL 116. The CESL 116 is formed of a material having a different etch rate than the first ILD 114, and may be formed of silicon nitride using PECVD, although other dielectric materials such as silicon oxide, silicon oxynitride, combinations thereof, or the like, and alternative techniques of forming the CESL 116, such as low-pressure CVD (LPCVD), PVD, or the like, could alternatively be used.

The first ILD 114 may be formed of a dielectric material, and may be deposited by any suitable method, such as CVD, PECVD, or FCVD. Dielectric materials for the first ILD 114 may include silicon oxide, Phospho-Silicate Glass (PSG), Boro-Silicate Glass (BSG), Boron-Doped Phospho-Silicate Glass (BPSG), undoped Silicate Glass (USG), or the like. Other insulation materials formed by any acceptable process may also be used.

After the formation of the first ILD 114, a planarization process, such as CMP, may be performed to level top surfaces of the first ILD 114 with top surfaces of the masks 104 and top surfaces of the gate spacers 108. In other embodiments, the planarization process may also remove the masks 104 on the dummy gate structures 103, and portions of the gate spacers 108 along sidewalls of the masks 104, such that, after the planarization process, top surfaces of the dummy gate structures 103, the gate spacers 108, and the first ILD 114 are level within process variations. Accordingly, the top surfaces of the dummy gates structures 103 are exposed through the first ILD 114.

FIGS. 19A, 19B, 20A, 20B, 21A, and 21B illustrate a replacement gate process performed subsequently, where the dummy gate structures 103 are removed and replaced by replacement gate structures 123 (e.g., metal gate structures).

In FIGS. 19A and 19B, the dummy gates 102 (e.g., and the masks 104 if present) are removed in an etching step(s), so that recesses 105 (which may also be referred to as gate trenches) are formed between respective gate spacers 108. In some embodiments, the dummy gates 102 are removed by an anisotropic dry etching process. For example, the etching process may include a dry etching process using reaction gas(es) that selectively etch the dummy gates 102 without etching the first ILD 114 and the gate spacers 108. During the removal of the dummy gates 102, the dummy gate dielectric 97 may be used as an etch stop layer when the dummy gates 102 are etched. The dummy gate dielectric 97 may then be removed after the removal of the dummy gates 102.

In some embodiments, the dummy gate dielectric 97 in the recesses 105 is removed. An etching process, such as an isotropic etching process, may be performed to remove the dummy gate dielectric 97. In an embodiment, an isotropic etching process using an etching gas that comprises HF and NH₃ is performed to remove the dummy gate dielectric 97. As illustrated in FIGS. 19A and 19B, each recess 105 exposes underlying channel regions of the NSFET device 100. Each channel region is disposed between neighboring pairs of the epitaxial source/drain regions 112.

Next, in FIGS. 20A and 20B, the disposable material 57 (e.g., portions exposed by the recesses 105) is removed to release the second semiconductor material 54, which may be referred to as the sheet formation process. After the disposable material 57 is removed, the second semiconductor material 54 (e.g., portions underlying the dummy gates 102 before the dummy gates 102 are removed) forms a plurality of nanostructures 54 that extend horizontally (e.g., parallel to a major upper surface of the substrate 50). The nanostructures 54 may be collectively referred to as the channel regions 93 or the channel layers 93 of the NSFET device 100. As illustrated in FIGS. 20A and 20B, gaps 53 (e.g., empty spaces) are formed between adjacent nanostructures 54 and between the lowermost nanostructure 54 and the fins 90 by the removal of the disposable material 57. In some embodiments, the nanostructures 54 are nanosheets or nanowires, depending on, e.g., the dimensions (e.g., size and/or aspect ratio) of the nanostructures 54.

In some embodiments, the disposable material 57 is removed by a selective etching process using an etchant that is selective to (e.g., having a higher etch rate for) the disposable material 57, such that the disposable material 57 is removed without substantially attacking the second semiconductor material 54. In some embodiments, an isotropic etching process, such as a wet etching process or the like, is performed to remove the disposable material 57. In embodiments where the disposable material 57 includes, e.g., SiO₂, and the second semiconductor material 54 includes, e.g., Si or SiC, hydrogen fluoride, diluted hydrogen fluoride, another fluorine-based etchant, or the like, may be used to remove the disposable material 57.

Advantages can be achieved by forming the dielectric liner 61 and the hard mask layer 73 over and in contact with the STI regions 96. These include the reduction of a risk of loss of a material of the STI region 96 during the selective etching process to remove the disposable material 57 as described in FIGS. 20A and 20B. As a result, an improvement in device reliability and device performance can be achieved.

Next, in FIGS. 21A and 21B, gate dielectric layers 120 and gate electrodes 122 are formed to form replacement gate structures 123. In some embodiments, a gate dielectric material 120 is deposited conformally in the recesses 105, such as on the top surfaces and the sidewalls of the fins 90, and on sidewalls of the gate spacers 108. The gate dielectric material 120 may also be formed on the top surface of the first ILD 114. Notably, the gate dielectric material 120 is formed to wrap around the nanostructures 54. In accordance with some embodiments, the gate dielectric material 120 comprises silicon oxide, silicon nitride, or multilayers thereof. In some embodiments, the gate dielectric material 120 comprises a high-k dielectric material, and in these embodiments, the gate dielectric material 120 may have a dielectric constant (e.g., K value) greater than about 7.0, and may include a metal oxide or a silicate of Hf, Al, Zr, La, Mg, Ba, Ti, or Pb, or combinations thereof. The formation methods of the gate dielectric material 120 may include Molecular-Beam Deposition (MBD), ALD, PECVD, and the like.

Next, a gate electrode material 122 is deposited over and around the gate dielectric material 120, to fill the remaining portions of the recesses 105. The gate electrode material 122 may include a metal-containing material such as TiN, TiO, TaN, TaC, Co, Ru, Al, W, combinations thereof, or multi-layers thereof. For example, although a single-layer gate electrode material 122 is illustrated, the gate electrode material 122 may comprise any number of liner layers (e.g., barrier layers), any number of work function tuning layers, and a fill metal material. After the filling of the gate electrode material 122, a planarization process, such as a CMP, may be performed to remove the excess portions of the gate dielectric material 120 and the gate electrode material 122, which excess portions are over the top surface of the first ILD 114. The remaining portions of the gate electrode material 122 and the gate dielectric material 120 thus form the gate electrodes 122 and the gate dielectric layers 120, respectively, of the replacement gate structures 123 of the NSFET device 100. Each gate electrode 122 and the corresponding gate dielectric layer 120 may be collectively referred to as a gate stack 123, a replacement gate structure 123, a metal gate structure 123, or a gate structure 123. Each gate structure 123 extends around the respective nanostructures 54. In an embodiment, after the gate dielectric layers 120 and the gate electrodes 122 are formed to form replacement gate structures 123, a portion of each fin 90 that protrudes above top surfaces of the dielectric liner 61 and the hard mask layer 73 may have a thickness T6 that is in a range from 1 nm to 10 nm. In an embodiment, a total thickness T7 of the dielectric liner 61 and the hard mask layer 73 may be in a range from 1 nm to 10 nm. In an embodiment, a ratio of the thickness T6 to the thickness T7 may be in a range from 1:10 to 10:1.

In FIGS. 22A and 22B, after the formation of the gate stacks 123, the gate stacks 123 (including the gate dielectric layers 120 and the corresponding overlying gate electrodes 122) may be recessed, and optional gate masks 130 may be formed in the recesses. In other embodiments, the gate stacks 123 may not be recessed and the gate masks 130 may not be formed in the recesses. After the gate masks 130 are formed in the recesses, a second ILD 132 is formed over the first ILD 114 and the gate masks 130. The recesses may be formed directly over the gate stacks 123 and between opposing portions of the gate spacers 108. The gate masks 130 may comprise one or more layers of dielectric material, such as silicon nitride, silicon oxynitride, or the like. A planarization process may be performed to remove excess material of the gate masks 130. The second ILD 132 may be formed of a dielectric material, such as PSG, BSG, BPSG, USG, or the like, and may be deposited by any suitable method, such as CVD, PECVD, FCVD, or the like.

In FIGS. 23A and 23B, the second ILD 132, the first ILD 114, the CESL 116, and the gate masks 130 are etched to form recesses exposing surfaces of the epitaxial source/drain regions 112 and/or some of the gate stacks 123. The recesses may be formed by etching using an anisotropic etching process, such as RIE, NBE, or the like. In some embodiments, the recesses may be etched through the second ILD 132 and the first ILD 114 using a first etching process; may be etched through the gate masks 130 using a second etching process; and may then be etched through the CESL 116 using a third etching process. A mask, such as a photoresist, may be formed and patterned over the second ILD 132 to mask portions of the second ILD 132 from the first etching process and the second etching process. In some embodiments, the etching process may over-etch, and therefore, the recesses extend into the epitaxial source/drain regions 112 and/or some of the gate stacks 123, and a bottom of the recesses may be level with (e.g., at a same level, or having a same distance from the substrate 50), or lower than (e.g., closer to the substrate 50) topmost surfaces of the epitaxial source/drain regions 112 and/or some of the gate stacks 123.

After the recesses are formed, first silicide regions 134 are formed over the epitaxial source/drain regions 112. In some embodiments, the first silicide regions 134 are formed by first depositing a metal (not separately illustrated) capable of reacting with the semiconductor materials of the underlying epitaxial source/drain regions 112 (e.g., silicon, silicon germanium, germanium) to form silicide or germanide regions, such as nickel, cobalt, titanium, tantalum, platinum, tungsten, other noble metals, other refractory metals, rare earth metals or their alloys, over the exposed portions of the epitaxial source/drain regions 112, and then performing a thermal annealing process to form the first silicide regions 134. The un-reacted portions of the deposited metal are then removed, e.g., by an etching process. Although the first silicide regions 134 are referred to as silicide regions, the first silicide regions 134 may also be germanide regions, or silicon germanide regions (e.g., regions comprising silicide and germanide).

Referring further to FIGS. 23A and 23B, source/drain contacts 136 and gate contacts 138, which may be also referred to as conductive contacts, are formed in the recesses. The source/drain contacts 136 and the gate contacts 138 may each comprise one or more layers, such as barrier layers, diffusion layers, and fill materials. For example, in some embodiments, the source/drain contacts 136 and the gate contacts 138 each include a barrier layer and a conductive material, and are each electrically connected to an underlying conductive feature (e.g., a gate electrode 122 and/or a first silicide region 134). The gate contacts 138 are electrically connected to the gate electrodes 122 and the source/drain contacts 136 are electrically connected to the first silicide regions 134. The barrier layer may include titanium, titanium nitride, tantalum, tantalum nitride, or the like. The conductive material may be copper, a copper alloy, silver, gold, tungsten, cobalt, aluminum, nickel, or the like. A planarization process, such as CMP, may be performed to remove excess material from surfaces of the second ILD 132. The structure shown in FIGS. 23A and 23B may be referred to as the NSFET device 100.

The embodiments of the present disclosure have some advantageous features. The embodiments include forming a semiconductor device that includes a shallow trench isolation (STI) region disposed between a first fin structure and a second fin structure, the first fin structure and the second fin structure protruding above a top surface of the STI region. A dielectric liner and a hard mask layer are sequentially formed over the STI region, and on top surfaces and sidewalls of portions of the first fin structure and the second fin structure that protrude above the STI region. An oxide capping layer may then be formed over the hard mask layer. A Bottom Anti-Reflective Coating (BARC) layer may be formed over the oxide capping layer in order to fill in a trench between the first fin structure and the second fin structure. A first etching process may be performed to etch-back the BARC layer, and a second etching process may be performed subsequently to remove portions of the oxide capping layer (e.g., on sidewalls and over top surfaces of the first fin structure and the second fin structure) that are above a top surface of the etched-back BARC layer. The etched-back BARC layer is then removed, and a third etching process is performed to remove portions of the hard mask layer that are over the top surfaces of the first fin structure and the second fin structure. Further, during the third etching process, portions of the hard mask layer that are on sidewalls of upper portions of the first fin structure and the second fin structure are removed, such that remaining portions of the hard mask layer are disposed over the STI region and on sidewalls of lower portions of the first fin structure and the second fin structure. After the third etching process is performed, portions of the dielectric liner on the top surfaces of the first fin structure and the second fin structure, as well as on the sidewalls of the upper portions of the first fin structure and the second fin structure are exposed. A fourth etching process is performed subsequently to remove the remaining portions of the oxide capping layer, portions of the hard mask layer on sidewalls of the first fin structure and the second fin structure, and portions of the dielectric liner that are disposed on sidewalls and top surfaces of the first fin structure and the second fin structure.

These advantageous features include the oxide capping layer reducing a risk of unwanted etching of the underlying hard mask layer during the first etching process, the third etching process, and the fourth etching process. As a result, unwanted etching of the hard mask layer and resulting thickness non-uniformities of the hard mask layer can be reduced. In addition, a larger and uniform thickness of the hard mask layer can be achieved over the top surfaces of the first fin structure and the second fin structure, as well as over the STI region. For example, horizontal portions of the hard mask layer that are disposed over the top surfaces of the first fin structure and the second fin structure and that have a reduced thickness and have thickness non-uniformities as a result of unwanted etching would increase a risk of etching damage and rounding of top corners of each of the first fin structure and the second fin structure (e.g., that include subsequently formed channel layers) during subsequent etching processes that may be performed to remove these horizontal portions. By reducing these thickness non-uniformities of the hard mask layer, device characteristics and performance can be preserved, and device reliability is increased. In addition, during a subsequent selective etching process that is used to form nanostructures of the semiconductor device, the larger thickness of hard mask layer over the STI region is able to provide increased protection to portions of the STI region from the selective etching process, and therefore, prevent or reduce loss of the STI region due to the selective etching process. As a result, device reliability can be improved.

In accordance with an embodiment, a method of forming a semiconductor device includes forming a first fin structure and a second fin structure that protrude above a substrate, the first fin structure being adjacent to the second fin structure, where each of the first fin structure and the second fin structure includes a fin and a layer stack over the fin, where the layer stack includes alternating layers of a first semiconductor material and a second semiconductor material; forming shallow trench isolation (STI) regions on opposing sides of each the first fin structure and the second fin structure; depositing a hard mask layer over the STI regions and top surfaces of the first fin structure and the second fin structure, and on sidewalls of the first fin structure and the second fin structure; depositing a capping layer over the hard mask layer; performing a first etching process to remove first portions of the capping layer and expose first portions of the hard mask layer on the sidewalls and over the first fin structure and the second fin structure; performing a second etching process to remove the exposed first portions of the hard mask layer; performing a third etching process to remove second portions of the hard mask layer on the sidewalls of the first fin structure and the second fin structure; and forming a dummy gate structure over the first fin structure, the second fin structure, and the STI regions, where a third portion of the hard mask layer is disposed between the dummy gate structure and the STI regions. In an embodiment, the hard mask layer includes silicon nitride, and the capping layer includes silicon oxide. In an embodiment, the method further includes prior to depositing the hard mask layer, depositing a dielectric liner over the STI regions and the top surfaces of the first fin structure and the second fin structure, and on the sidewalls of the first fin structure and the second fin structure. In an embodiment, the method further includes after depositing the capping layer over the hard mask layer, and prior to performing the first etching process to remove the first portions of the capping layer, forming a Bottom Anti-Reflective Coating (BARC) layer over the capping layer to fill a trench between the first fin structure and the second fin structure; and etching-back the BARC layer to expose the first portions of the capping layer. In an embodiment, the method further includes forming source/drain openings in the first fin structure on opposing sides of the dummy gate structure, where the source/drain openings expose the first semiconductor material and the second semiconductor material; and after forming the source/drain openings, replacing the first semiconductor material disposed under the dummy gate structure with a sacrificial material. In an embodiment, performing the first etching process includes performing a dry etching process or a wet etching process using hydrogen fluoride as an etchant. In an embodiment, performing the second etching process includes performing a wet etching process using phosphoric acid (H₃PO₄) as an etchant. In an embodiment, performing the third etching process includes performing a wet etching process using hydrogen fluoride as an etchant. In an embodiment, performing the third etching process further includes etching remaining portions of the capping layer.

In accordance with an embodiment, a method of forming a semiconductor device includes forming a fin structure that protrudes above shallow trench isolation (STI) regions, where the STI regions are over a substrate and on opposing sides of the fin structure, where the fin structure includes a fin and a layer stack over the fin, where the layer stack includes alternating layers of a first semiconductor material and a second semiconductor material; depositing a hard mask layer over the STI regions and a top surface of the fin structure, and on sidewalls of the fin structure; depositing a capping layer over the hard mask layer; performing a first etching process to remove first portions of the capping layer and expose first portions of the hard mask layer on the sidewalls of and over the fin structure; performing a second etching process to remove the exposed first portions of the hard mask layer; performing a third etching process to remove second portions of the hard mask layer on the sidewalls of the fin structure; and forming a dummy gate over the fin structure and the STI regions, where remaining portions of the hard mask layer are disposed between the STI regions and the dummy gate. Ina n embodiment, a material of the hard mask layer is different from a material of the capping layer. In an embodiment, the material of the capping layer includes silicon oxide. In an embodiment, the method further includes forming source/drain openings in the fin structure on opposing sides of the dummy gate; and after forming the source/drain openings, replacing the first semiconductor material disposed under the dummy gate with a sacrificial material. In an embodiment, after the third etching process, upper surfaces of the remaining portions of the hard mask layer over the STI regions are convex surfaces. In an embodiment, performing the third etching process further includes etching remaining portions of the capping layer.

In accordance with an embodiment, a method includes depositing a multi-layer stack over a semiconductor substrate, the multi-layer stack including alternating layers of a first semiconductor material and a second semiconductor material; forming a fin structure from the multi-layer stack and the semiconductor substrate, the fin structure including a fin and a layer stack over the fin, where the layer stack includes the alternating layers of the first semiconductor material and the second semiconductor material; forming shallow trench isolation (STI) regions on opposing sides of the fin structure; depositing a hard mask layer over the STI regions and a top surface of the fin structure, and on sidewalls of the fin structure, where depositing the hard mask layer is performed in a first process chamber; depositing a capping layer over the hard mask layer, where depositing the capping layer is performed in the first process chamber; performing a first etching process to remove first portions of the capping layer and expose first portions of the hard mask layer on the sidewalls of and over the fin structure; performing a second etching process to remove the exposed first portions of the hard mask layer; and after performing the second etching process, forming a dummy gate over the fin structure and remaining portions of the hard mask layer, where the remaining portions of the hard mask layer are disposed over the STI regions. In an embodiment, the method further includes after performing the second etching process, and prior to forming the dummy gate over the fin structure and the remaining portions of the hard mask layer, performing a third etching process to remove remaining portions of the capping layer, and second portions of the hard mask layer on the sidewalls of the fin structure. In an embodiment, the method further includes forming source/drain openings in the fin structure on opposing sides of the dummy gate; after forming the source/drain openings, replacing the first semiconductor material disposed under the dummy gate with a sacrificial material; and after the replacing, forming source/drain regions in the source/drain openings. In an embodiment, the method further includes forming an interlayer dielectric (ILD) layer over the source/drain regions and around the dummy gate; removing the dummy gate to form a gate trench in the ILD layer, where the gate trench exposes the sacrificial material and a first portion of the second semiconductor material; selectively removing the exposed sacrificial material, where after the selectively removing, the first portion of the second semiconductor material form nanostructures; and forming a replacement gate structure around the nanostructures. In an embodiment, the hard mask layer includes silicon nitride, and the capping layer includes silicon oxide.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor device, the method comprising:
forming a first fin structure and a second fin structure that protrude above a substrate, the first fin structure being adjacent to the second fin structure, wherein each of the first fin structure and the second fin structure comprises a fin and a layer stack over the fin, wherein the layer stack comprises alternating layers of a first semiconductor material and a second semiconductor material;
forming shallow trench isolation (STI) regions on opposing sides of each the first fin structure and the second fin structure;
depositing a hard mask layer over the STI regions and top surfaces of the first fin structure and the second fin structure, and on sidewalls of the first fin structure and the second fin structure;
depositing a capping layer over the hard mask layer;
performing a first etching process to remove first portions of the capping layer and expose first portions of the hard mask layer on the sidewalls and over the first fin structure and the second fin structure;
performing a second etching process to remove the exposed first portions of the hard mask layer;
performing a third etching process to remove second portions of the hard mask layer on the sidewalls of the first fin structure and the second fin structure; and
forming a dummy gate structure over the first fin structure, the second fin structure, and the STI regions, wherein a third portion of the hard mask layer is disposed between the dummy gate structure and the STI regions.

2. The method of claim 1, wherein the hard mask layer comprises silicon nitride, and the capping layer comprises silicon oxide.

3. The method of claim 1, further comprising:
prior to depositing the hard mask layer, depositing a dielectric liner over the STI regions and the top surfaces of the first fin structure and the second fin structure, and on the sidewalls of the first fin structure and the second fin structure.

4. The method of claim 1, further comprising:
after depositing the capping layer over the hard mask layer, and prior to performing the first etching process to remove the first portions of the capping layer, forming a Bottom Anti-Reflective Coating (BARC) layer over the capping layer to fill a trench between the first fin structure and the second fin structure; and
etching-back the BARC layer to expose the first portions of the capping layer.

5. The method of claim 1, further comprising:
forming source/drain openings in the first fin structure on opposing sides of the dummy gate structure, wherein the source/drain openings expose the first semiconductor material and the second semiconductor material; and
after forming the source/drain openings, replacing the first semiconductor material disposed under the dummy gate structure with a sacrificial material.

6. The method of claim 1, wherein performing the first etching process comprises performing a dry etching process or a wet etching process using hydrogen fluoride as an etchant.

7. The method of claim 1, wherein performing the second etching process comprises performing a wet etching process using phosphoric acid (H₃PO₄) as an etchant.

8. The method of claim 1, wherein performing the third etching process comprises performing a wet etching process using hydrogen fluoride as an etchant.

9. The method of claim 8, wherein performing the third etching process further comprises etching remaining portions of the capping layer.

10. A method of forming a semiconductor device, the method comprising:
forming a fin structure that protrudes above shallow trench isolation (STI) regions, wherein the STI regions are over a substrate and on opposing sides of the fin structure, wherein the fin structure comprises a fin and a layer stack over the fin, wherein the layer stack comprises alternating layers of a first semiconductor material and a second semiconductor material;
depositing a hard mask layer over the STI regions and a top surface of the fin structure, and on sidewalls of the fin structure;
depositing a capping layer over the hard mask layer;
performing a first etching process to remove first portions of the capping layer and expose first portions of the hard mask layer on the sidewalls of and over the fin structure;
performing a second etching process to remove the exposed first portions of the hard mask layer;
performing a third etching process to remove second portions of the hard mask layer on the sidewalls of the fin structure; and
forming a dummy gate over the fin structure and the STI regions, wherein remaining portions of the hard mask layer are disposed between the STI regions and the dummy gate.

11. The method of claim 10, wherein a material of the hard mask layer is different from a material of the capping layer.

12. The method of claim 11, wherein the material of the capping layer comprises silicon oxide.

13. The method of claim 10, further comprising:
forming source/drain openings in the fin structure on opposing sides of the dummy gate; and
after forming the source/drain openings, replacing the first semiconductor material disposed under the dummy gate with a sacrificial material.

14. The method of claim 10, wherein after the third etching process, upper surfaces of the remaining portions of the hard mask layer over the STI regions are convex surfaces.

15. The method of claim 10, wherein performing the third etching process further comprises etching remaining portions of the capping layer.

16. A method comprising:
depositing a multi-layer stack over a semiconductor substrate, the multi-layer stack comprising alternating layers of a first semiconductor material and a second semiconductor material;
forming a fin structure from the multi-layer stack and the semiconductor substrate, the fin structure comprising a fin and a layer stack over the fin, wherein the layer stack comprises the alternating layers of the first semiconductor material and the second semiconductor material;
forming shallow trench isolation (STI) regions on opposing sides of the fin structure;
depositing a hard mask layer over the STI regions and a top surface of the fin structure, and on sidewalls of the fin structure, wherein depositing the hard mask layer is performed in a first process chamber;
depositing a capping layer over the hard mask layer, wherein depositing the capping layer is performed in the first process chamber;
performing a first etching process to remove first portions of the capping layer and expose first portions of the hard mask layer on the sidewalls of and over the fin structure;
performing a second etching process to remove the exposed first portions of the hard mask layer; and
after performing the second etching process, forming a dummy gate over the fin structure and remaining portions of the hard mask layer, wherein the remaining portions of the hard mask layer are disposed over the STI regions.

17. The method of claim 16, further comprising:
after performing the second etching process, and prior to forming the dummy gate over the fin structure and the remaining portions of the hard mask layer, performing a third etching process to remove remaining portions of the capping layer, and second portions of the hard mask layer on the sidewalls of the fin structure.

18. The method of claim 16, further comprising:
forming source/drain openings in the fin structure on opposing sides of the dummy gate;
after forming the source/drain openings, replacing the first semiconductor material disposed under the dummy gate with a sacrificial material; and
after the replacing, forming source/drain regions in the source/drain openings.

19. The method of claim 18, further comprising:
forming an interlayer dielectric (ILD) layer over the source/drain regions and around the dummy gate;
removing the dummy gate to form a gate trench in the ILD layer, wherein the gate trench exposes the sacrificial material and a first portion of the second semiconductor material;
selectively removing the exposed sacrificial material, wherein after the selectively removing, the first portion of the second semiconductor material form nanostructures; and
forming a replacement gate structure around the nanostructures.

20. The method of claim 16, wherein the hard mask layer comprises silicon nitride, and the capping layer comprises silicon oxide.
